(19) United States
(12) Patent Application Publication
(10) Pub. No.: US 2026/0231395 A1
(43) Pub. Date: Aug. 6, 2026

(54) SEMICONDUCTOR DEVICE AND SEMICONDUCTOR MEMORY DEVICE

(71) Applicant: Kioxia Corporation, Tokyo (JP)

(72) Inventors: Tatsuki KIKUCHI, Yokkaichi Mie (JP); Kenichi HAGA, Yokkaichi Mie (JP); Keiji IKEDA, Yokkaichi Mie (JP)

(21) Appl. No.: 19/334,201

(22) Filed: Sep. 19, 2025

(30) Foreign Application Priority Data
Jan. 30, 2025 (JP) 2025-014280

(51) Int. Cl. H10B 12/00

(52) U.S. Cl. CPC H10B 12/33; H10B 12/05

(57) ABSTRACT

According to one embodiment, a semiconductor device includes a gate electrode extending in a first direction and a oxide semiconductor layer extending in a second direction through a portion of the gate electrode between first and second electrodes. The gate electrode faces the oxide semiconductor layer at a position between the first and second electrodes. A gate insulating layer surrounds the oxide semiconductor layer. The gate insulating layer is between the gate electrode and the oxide semiconductor layer and includes at least one combination of elements selected from the group consisting of silicon and nitrogen, titanium and oxygen, and aluminum and oxygen. A first insulating layer includes a first portion and a second portion. The gate electrode is between the first and second portions in a third direction. The first portion contacts the gate insulating layer, and the second portion contacts the gate electrode.

### CROSS-REFERENCE TO RELATED APPLICATION

This application is based upon and claims the benefit of priority from Japanese Patent Application No. 2025-014280, filed January 30, 2025, the entire contents of which are incorporated herein by reference.

### FIELD

Embodiments described herein relate generally to a semiconductor device and a semiconductor memory device.

### BACKGROUND

So-called oxide semiconductor transistors, which rely on a channel being formed in an oxide semiconductor layer, have excellent characteristics such as having an extremely small channel leakage current during a turn-off operation. For such reasons, oxide semiconductor transistors are applied to switching transistors in memory cells of dynamic random access memories (DRAMs).

### BRIEF DESCRIPTION OF THE DRAWINGS

FIG. 1 is a schematic cross-sectional view of a semiconductor device according to a first embodiment.

FIG. 2 is a schematic cross-sectional view of the semiconductor device according to the first embodiment.

FIG. 3 is a schematic cross-sectional view of the semiconductor device according to the first embodiment.

FIG. 4 is an enlarged schematic cross-sectional view of the semiconductor device according to the first embodiment.

FIG. 5 is an enlarged schematic cross-sectional view of the semiconductor device according to the first embodiment.

FIGS. 6 to 19 are schematic cross-sectional views showing an example of a method of manufacturing the semiconductor device according to the first embodiment.

FIG. 20 is a schematic cross-sectional view of a semiconductor device according to a comparative example.

FIG. 21 is a schematic cross-sectional view of the semiconductor device according to a comparative example.

FIG. 22 is a schematic cross-sectional view of a semiconductor device according to a second embodiment.

FIG. 23 is a schematic cross-sectional view of the semiconductor device according to the second embodiment.

FIG. 24 is a schematic cross-sectional view of the semiconductor device according to the second embodiment.

FIG. 25 is an enlarged schematic cross-sectional view of the semiconductor device according to the second embodiment.

FIG. 26 is an enlarged schematic cross-sectional view of the semiconductor device according to the second embodiment.

FIGS. 27 to 35 are schematic cross-sectional views showing an example of a method of manufacturing the semiconductor device according to the second embodiment.

FIG. 36 is a schematic cross-sectional view of a semiconductor device according to a third embodiment.

FIG. 37 is a schematic cross-sectional view of the semiconductor device according to the third embodiment.

FIG. 38 is a schematic cross-sectional view of the semiconductor device according to the third embodiment.

FIG. 39 is a schematic cross-sectional view of the semiconductor device according to the third embodiment.

FIG. 40 is a schematic cross-sectional view of a semiconductor device according to a fourth embodiment.

FIG. 41 is a schematic cross-sectional view of the semiconductor device according to the fourth embodiment.

FIG. 42 is a schematic cross-sectional view of the semiconductor device according to the fourth embodiment.

FIG. 43 is a schematic cross-sectional view of the semiconductor device according to the fourth embodiment.

FIG. 44 is an equivalent circuit diagram of a semiconductor memory device according to a fifth embodiment.

FIG. 45 is a schematic cross-sectional view of the semiconductor memory device according to the fifth embodiment.

### DETAILED DESCRIPTION

Embodiments provide a semiconductor device with excellent transistor characteristics.

In general, according to one embodiment, a semiconductor device includes: a first electrode, a second electrode, and a gate electrode. The gate electrode extends in a first direction. A first oxide semiconductor layer extends in a second direction through a portion of the gate electrode. The first oxide semiconductor layer extends in the second direction between the first electrode and the second electrode. The gate electrode faces the first oxide semiconductor layer at a position between the first and second electrodes in the second direction. A first gate insulating layer surrounds the first oxide semiconductor layer. The first gate insulating layer is between the gate electrode and the first oxide semiconductor layer and includes at least one combination of elements selected from the group consisting of silicon and nitrogen, titanium and oxygen, and aluminum and oxygen. A first insulating layer has a first portion and a second portion. The gate electrode is between the first portion and the second portion in a third direction. The first portion contacts the first gate insulating layer, and the second portion contacts the gate electrode.

Hereinafter, certain example embodiments of the present disclosure will be described with reference to the drawings. In the following description, the same or substantially similar components and the like are denoted by the same reference symbols, and the description of components and the like that have already been described may be omitted as appropriate.

Further, in this specification, the terms "upper", "lower", "upper part", and "lower part" may be used for descriptive convenience. In this context, terms "upper", "lower", "upper part", and "lower part" merely indicate relative positional relationships in the drawings, and do not necessarily define positional relationships with respect to gravity.

In this specification, qualitative and quantitative analysis of chemical compositions of materials that configure a semiconductor device and a semiconductor memory device can be performed using, for example, secondary ion mass spectrometry (SIMS), energy dispersive X-ray spectroscopy (EDX), or Rutherford back-scattering spectroscopy (RBS). In addition, for example, a transmission electron microscope (TEM) may be used to measure the thicknesses of the materials or components configuring a semiconductor device and a semiconductor memory device, distances between the materials or components, crystal grain sizes, and the like. In addition, X-ray photoelectron spectroscopy (XPS), hard X-ray photoelectron spectroscopy (HAXPES), and electron energy loss spectroscopy (EELS) may be used to identify the constituent materials of components or the like configuring a semiconductor device and a semiconductor memory device and to measure the proportions or ratios of the constituent materials therein.

In this specification, the term "metal" is a general term for materials that exhibit metallic properties, and for example, metal compounds such as metal nitrides and metal carbides that exhibit metallic properties are also within the scope of "metal" as used herein.

### First Embodiment

A semiconductor device according to a first embodiment includes a first electrode, a second electrode, a first oxide semiconductor layer that is provided between the first electrode and the second electrode, a gate electrode that faces the first oxide semiconductor layer and extends in a first direction, a first gate insulating layer that is provided between the gate electrode and the first oxide semiconductor layer, surrounds the first oxide semiconductor layer, and contains at least one combination of elements selected from the group consisting of a combination of silicon (Si) and nitrogen (N), a combination of titanium (Ti) and oxygen (O), and a combination of aluminum (Al) and oxygen (O), and a first insulating layer that includes a first portion and a second portion in a first cross section perpendicular to a second direction connecting the first electrode and the second electrode and including the gate electrode, the gate electrode being provided between the first portion and the second portion, the first portion being in contact with the first gate insulating layer, and the second portion being in contact with the gate electrode.

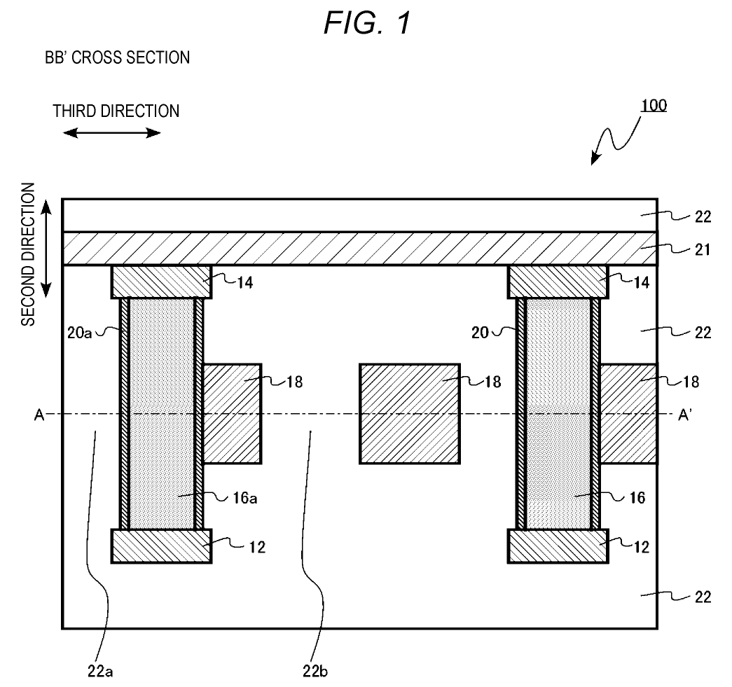

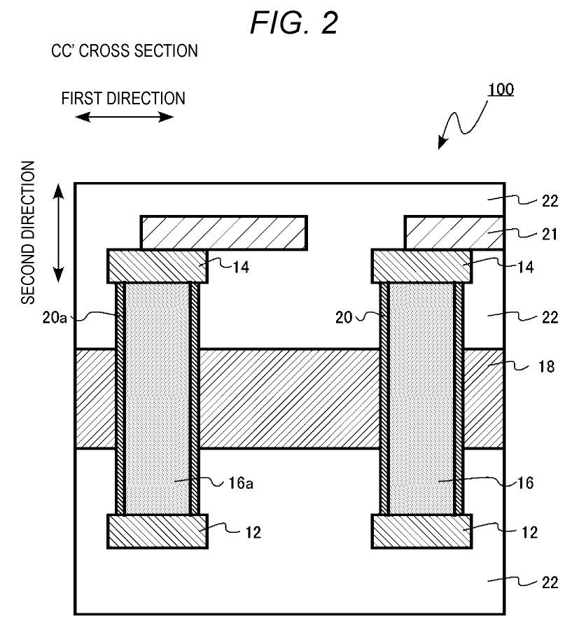

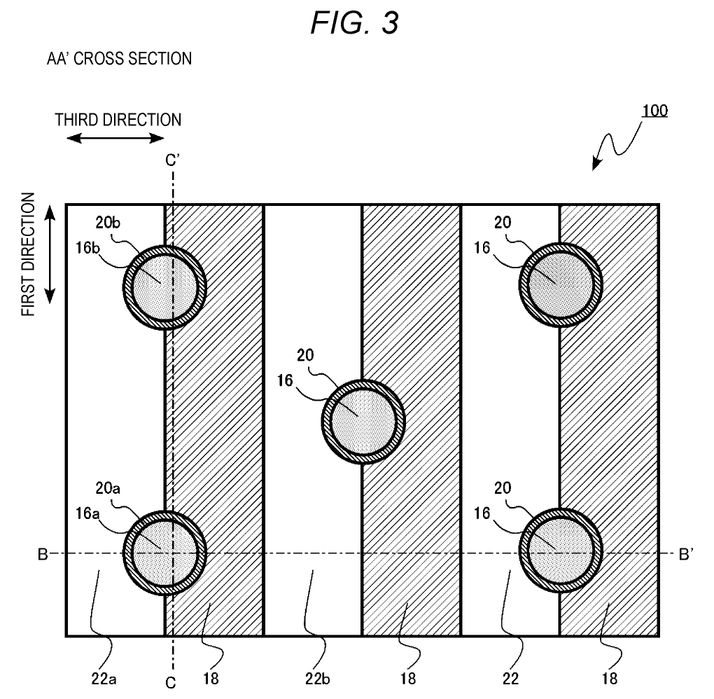

FIGS. 1, 2, and 3 are schematic cross-sectional views of the semiconductor device according to the first embodiment. FIG. 3 is a cross-sectional view taken along line AA' in FIG. 1. FIG. 1 is a cross-sectional view taken along line BB' in FIG. 3. FIG. 2 is a cross-sectional view taken along line CC' in FIG. 3.

In FIG. 1, the up-down direction is a second direction. In FIG. 1, the right-left direction is a third direction. In FIG. 2, the up-down direction is the second direction and the right-left direction is a first direction. In FIG. 3, the up-down direction is the first direction. In FIG. 3, the right-left direction is the third direction.

The second direction and the third direction are perpendicular to the first direction. The third direction is perpendicular to the second direction. The second direction is a direction going from a lower electrode 12 and an upper electrode 14.

FIGS. 1 and 2 are cross sections parallel to the second direction. FIG. 3 is a cross section perpendicular to the second direction. FIG. 3 is an example of a first cross section.

The semiconductor device according to the first embodiment is a transistor 100. The transistor 100 is an oxide semiconductor transistor in which a channel is formed in an oxide semiconductor material. The transistor 100 is a so-called vertical transistor. The transistor 100 includes a plurality of individual transistors.

The transistor 100 includes a lower electrode 12, an upper electrode 14, an oxide semiconductor layer 16, a gate electrode 18, a gate insulating layer 20, a first wiring layer 21, and an interlayer insulating layer 22. The oxide semiconductor layer 16 can be a first oxide semiconductor layer 16a or a second oxide semiconductor layer 16b. Individual oxide semiconductor layers 16 may be referred to as an oxide semiconductor column or column-shaped oxide semiconductor layer in some contexts. The gate insulating layers 20 include a first gate insulating layer 20a and a second gate insulating layer 20b. The interlayer insulating layer 22 includes a first portion 22a and a second portion 22b.

The lower electrode 12 is an example of a first electrode. The upper electrode 14 is an example of a second electrode. The interlayer insulating layer 22 is an example of a first insulating layer.

The lower electrode 12, the upper electrode 14, the oxide semiconductor layer 16, the gate electrode 18, and the gate insulating layer 20 configure one transistor. Each of the plurality of transistors in transistor 100 has the same configuration. Below, the configuration of these transistors is described using a transistor including the first oxide semiconductor layer 16a or the second oxide semiconductor layer 16b among the plurality of transistors as representative examples.

The lower electrode 12 is provided below the oxide semiconductor layer 16. The lower electrode 12 is electrically connected to the oxide semiconductor layer 16. The lower electrode 12 is in contact with, for example, the oxide semiconductor layer 16. The lower electrode 12 functions as a source electrode or a drain electrode of the transistor 100.

The lower electrode 12 is a conductor. The lower electrode 12 comprises, for example, an oxide conductor. The lower electrode 12 is, for example, an oxide conductor layer.

The lower electrode 12 comprises, for example, indium (In), tin (Sn), and oxygen (O). The lower electrode 12 comprises, for example, indium tin oxide. The lower electrode 12 is, for example, an indium tin oxide layer.

The lower electrode 12 comprises, for example, tin (Sn) and oxygen (O). The lower electrode 12 comprises, for example, tin oxide. The lower electrode 12 is, for example, a tin oxide layer.

The lower electrode 12 comprises, for example, a metal. The lower electrode 12 is, for example, a metal layer.

The lower electrode 12 comprises, for example, tungsten (W), molybdenum (Mo), copper (Cu), aluminum (Al), titanium (Ti), or tantalum (Ta). The lower electrode 12 is, for example, a tungsten layer, a molybdenum layer, a copper layer, an aluminum layer, a titanium layer, or a tantalum layer.

The lower electrode 12 may have, for example, a stacked structure including a plurality of conductors. The lower electrode 12 is, for example, a stacked structure including an oxide conductor layer and a metal layer. For example, the surface of the lower electrode 12 on the oxide semiconductor layer 16 side is an oxide conductor layer.

The upper electrode 14 is provided on the oxide semiconductor layer 16. The upper electrode 14 is electrically connected to the oxide semiconductor layer 16. The upper electrode 14 can be in contact with the oxide semiconductor layer 16, for example. The upper electrode 14 functions as a source electrode or a drain electrode of the transistor 100.

The upper electrode 14 is a conductor. The upper electrode 14 can comprise or be an oxide conductor, for example.

The upper electrode 14 comprises, for example, indium (In), tin (Sn), and oxygen (O). The upper electrode 14 comprises, for example, indium tin oxide. The upper electrode 14 is, for example, an indium tin oxide layer.

In some examples, upper electrode 14 comprises tin (Sn) and oxygen (O). For example, the upper electrode 14 comprises, tin oxide or is a tin oxide layer.

In some examples, upper electrode 14 comprises a metal. The upper electrode 14 can be a metal layer, for example.

In some examples, upper electrode 14 comprises tungsten (W), molybdenum (Mo), copper (Cu), aluminum (Al), titanium (Ti), or tantalum (Ta). The upper electrode 14 can be, for example, a tungsten layer, a molybdenum layer, a copper layer, an aluminum layer, a titanium layer, or a tantalum layer.

The upper electrode 14 may have a stacked structure of a plurality of conductors. The upper electrode 14 is, for example, a stacked structure of an oxide conductor layer and a metal layer. For example, the surface of the upper electrode 14 on the oxide semiconductor layer 16 side is an oxide conductor layer. The upper electrode 14 comprises, for example, titanium oxide.

The lower electrode 12 and the upper electrode 14 can be formed of the same material in some examples. The lower electrode 12 and the upper electrode 14 are, for example, oxide conductors comprising indium (In), tin (Sn), and oxygen (O). The lower electrode 12 and the upper electrode 14 may be, for example, indium tin oxide. The lower electrode 12 and the upper electrode 14 are, for example, indium tin oxide layers.

The first oxide semiconductor layer 16a is provided between the lower electrode 12 and the upper electrode 14. The first oxide semiconductor layer 16a is in contact with the lower electrode 12. The first oxide semiconductor layer 16a is also in contact with the upper electrode 14.

The second oxide semiconductor layer 16b is provided in a first direction from the first oxide semiconductor layer 16a.

As shown in FIG. 3, the first oxide semiconductor layer 16a is circular in a cross section perpendicular to the second direction and including the gate electrode 18.

In the first oxide semiconductor layer 16a, a channel that serves as a current path during a turn-on operation of the transistor 100 is formed. That is, when the transistor 100 is in an ON state current flows in the channel/current path.

The first oxide semiconductor layer 16a is an oxide semiconductor material. The first oxide semiconductor layer 16a is, for example, amorphous.

The first oxide semiconductor layer 16a includes, for example, oxygen (O) and at least one element selected from the group consisting of indium (In), gallium (Ga), silicon (Si), aluminum (Al), and tin (Sn), zinc (Zn). In some examples, the first oxide semiconductor layer 16a includes indium (In), gallium (Ga), zinc (Zn), and oxygen (O). The first oxide semiconductor layer 16a is, for example, an indium gallium zinc oxide. The first oxide semiconductor layer 16a is, for example, an indium gallium zinc oxide layer.

In some examples, the first oxide semiconductor layer 16a includes oxygen (O) and at least one element selected from the group consisting of titanium (Ti), zinc (Zn), and tungsten (W). The first oxide semiconductor layer 16a comprises, for example, titanium oxide, zinc oxide, or tungsten oxide. The first oxide semiconductor layer 16a is, for example, a titanium oxide layer, a zinc oxide layer, or a tungsten oxide layer.

In some examples, the first oxide semiconductor layer 16a has a chemical composition different from the chemical composition of the lower electrode 12 and the chemical composition of the upper electrode 14.

The first oxide semiconductor layer 16a includes oxygen vacancies. The oxygen vacancies in the first oxide semiconductor layer 16a function as donors.

The length of the first oxide semiconductor layer 16a in the first direction is, for example, 15 nm to 200 nm. The length of the first oxide semiconductor layer 16a in the second direction is, for example, 10 nm to 100 nm.

The gate electrode 18 faces the first oxide semiconductor layer 16a. The gate electrode 18 also faces the second oxide semiconductor layer 16b.

The gate electrode 18 extends in the first direction.

The gate electrode 18 is provided such that its position coordinate in the second direction is a value between the position coordinates of the lower electrode 12 and the upper electrode 14 in the second direction.

The gate electrode 18 is a conductor. The gate electrode 18 can be a metal, a metal compound, or a semiconductor. The gate electrode 18 comprises, for example, tungsten (W).

The length of the gate electrode 18 in the third direction is, for example, 10 nm to 100 nm.

The first gate insulating layer 20a is provided between the first oxide semiconductor layer 16a and the gate electrode 18. The first gate insulating layer 20a surrounds the first oxide semiconductor layer 16a. The first gate insulating layer 20a is in contact with the first oxide semiconductor layer 16a.

The second gate insulating layer 20b is provided between the second oxide semiconductor layer 16b and the gate electrode 18. The second gate insulating layer 20b surrounds the second oxide semiconductor layer 16b. The second gate insulating layer 20b is in contact with the second oxide semiconductor layer 16b.

In a cross section perpendicular to the second direction and including the gate electrode 18, a part of the first gate insulating layer 20a is in contact with the gate electrode 18. In a cross section perpendicular to the second direction and including the gate electrode 18, another part of the first gate insulating layer 20a is in contact with the first portion 22a of the interlayer insulating layer 22. The first gate insulating layer 20a is in contact with the lower electrode 12 and the upper electrode 14.

In a cross section perpendicular to the second direction and including the gate electrode 18, a part of the second gate insulating layer 20b is in contact with the gate electrode 18. In a cross section perpendicular to the second direction and including the gate electrode 18, another part of the second gate insulating layer 20b is in contact with the first portion 22a of the interlayer insulating layer 22.

The first gate insulating layer 20a includes at least one combination of elements selected from the group of combinations consisting of silicon (Si) and nitrogen (N), titanium (Ti) and oxygen (O), and aluminum (Al) and oxygen (O). For example, the first gate insulating layer 20a comprises at least one compound selected from the group consisting of silicon nitride, titanium oxide, and aluminum oxide. For example, the first gate insulating layer 20a includes a silicon nitride film, a titanium oxide film, or an aluminum oxide film.

The second gate insulating layer 20b includes at least one combination of elements selected from the group of combinations consisting of silicon (Si) and nitrogen (N), titanium (Ti) and oxygen (O), and aluminum (Al) and oxygen (O).

In some examples, the first gate insulating layer 20a may have a stacked structure. The thickness of the first gate insulating layer 20a is, for example, between 2 nm and 10 nm.

The first wiring layer 21 extends in the third direction. The first wiring layer 21 is, for example, repeatedly provided in the first direction. The first wiring layer 21 is electrically connected to the upper electrode 14. The first wiring layer 21 is, for example, provided on the upper electrode 14.

The first wiring layer 21 is, for example, a metal.

The interlayer insulating layer 22 surrounds the lower electrode 12, the upper electrode 14, the oxide semiconductor layer 16, the gate insulating layer 20, and the first wiring layer 21. The interlayer insulating layer 22 is provided, for example, between the lower electrode 12 and the gate electrode 18. The interlayer insulating layer 22 is provided, for example, between the upper electrode 14 and the gate electrode 18.

The interlayer insulating layer 22 includes the first portion 22a and the second portion 22b. As shown in FIG. 3, in a cross section perpendicular to the second direction, the gate electrode 18 is provided between the first portion 22a and the second portion 22b.

The first gate insulating layer 20a is provided between the first portion 22a and the first oxide semiconductor layer 16a. The first portion 22a and the first gate insulating layer 20a are in contact with each other. The second portion 22b and the gate electrode 18 are in contact with each other.

The second gate insulating layer 20b is provided between the first portion 22a and the second oxide semiconductor layer 16b. The first portion 22a and the second gate insulating layer 20b are in contact with each other.

The interlayer insulating layer 22 is an insulator. The interlayer insulating layer 22 can be, for example, an oxide, a nitride, or an oxynitride. In some examples, the interlayer insulating layer 22 comprises silicon (Si) and oxygen (O). For example, the interlayer insulating layer 22 comprises or is silicon oxide.

In some examples, the interlayer insulating layer 22 can be or incorporate an air gap (void containing gas).

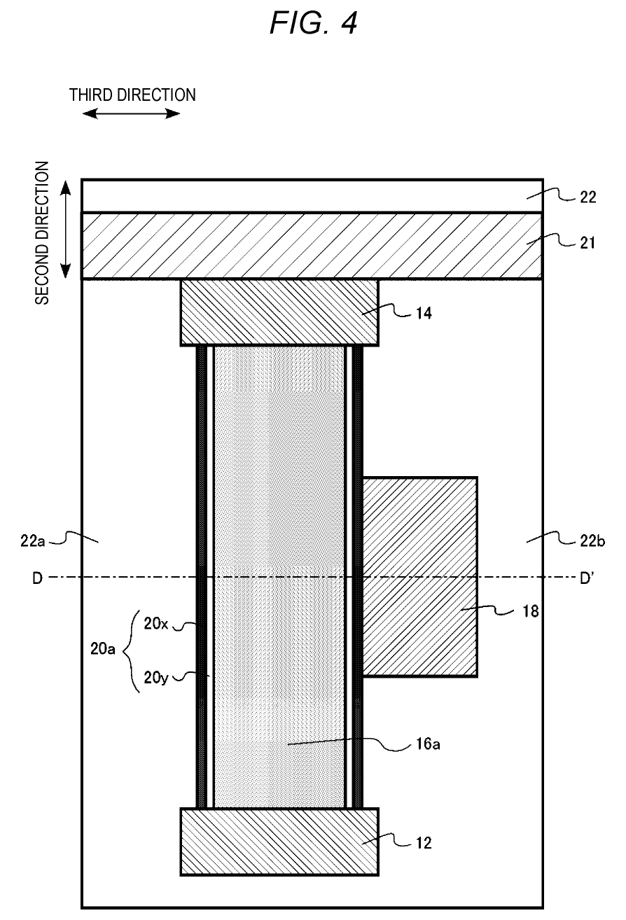

FIGS. 4 and 5 are enlarged schematic cross-sectional views of the semiconductor device according to the first embodiment. FIG. 4 is an enlarged cross-sectional view of a portion of FIG. 1. FIG. 5 is an enlarged cross-sectional view of a portion of FIG. 3. FIG. 5 is a cross-sectional view taken along line DD' in FIG. 4.

As shown in FIG. 4 and FIG. 5, the first gate insulating layer 20a includes a first film 20x and a second film 20y. The first gate insulating layer 20a has a stacked structure of the first film 20x and the second film 20y. The second film 20y is provided between the first film 20x and the first oxide semiconductor layer 16a.

In some examples, first film 20x comprises at least one combination of elements selected from the group of combinations consisting of silicon (Si) and nitrogen (N), titanium (Ti) and oxygen (O), and aluminum (Al) and oxygen (O). For example, the first film 20x includes at least one compound selected from the group consisting of silicon nitride, titanium oxide, and aluminum oxide. The first film 20x is, for example, a silicon nitride film, a titanium oxide film, or an aluminum oxide film.

The chemical composition of the second film 20y is different from the chemical composition of the first film 20x. The second film 20y comprises, for example, silicon (Si) and oxygen (O). In some examples, second film 20y comprises silicon oxide or is a silicon oxide film.

As shown in FIG. 5, in a cross section perpendicular to the second direction and including the gate electrode 18, the shape of the first oxide semiconductor layer 16a is circular. A part of the first oxide semiconductor layer 16a protrudes in the third direction into the gate electrode 18. In addition, a part of the first gate insulating layer 20a protrudes in the third direction into to the gate electrode 18.

As shown in FIG. 5, a maximum distance (d1 in FIG. 5) in the third direction perpendicular to the first direction between an edge of the first oxide semiconductor layer 16a on the first portion 22a side and an edge of the gate electrode 18 on the second portion 22b side is greater than the maximum width (w in FIG. 5) of the gate electrode 18 in the third direction.

As shown in FIG. 5, the minimum distance (d2 in FIG. 5) in the third direction perpendicular to the first direction between the first gate insulating layer 20a and an edge of the gate electrode 18 on the second portion 22b side is, for example, at least one-third of the maximum width (w in FIG. 5) of the gate electrode 18 in the third direction.

As shown in FIG. 5, a part of the first gate insulating layer 20a is in contact with the gate electrode 18. Another part of the first gate insulating layer 20a is in contact with the first portion 22a of the interlayer insulating layer 22.

Next, an example of a method of manufacturing the semiconductor device according to the first embodiment will be described.

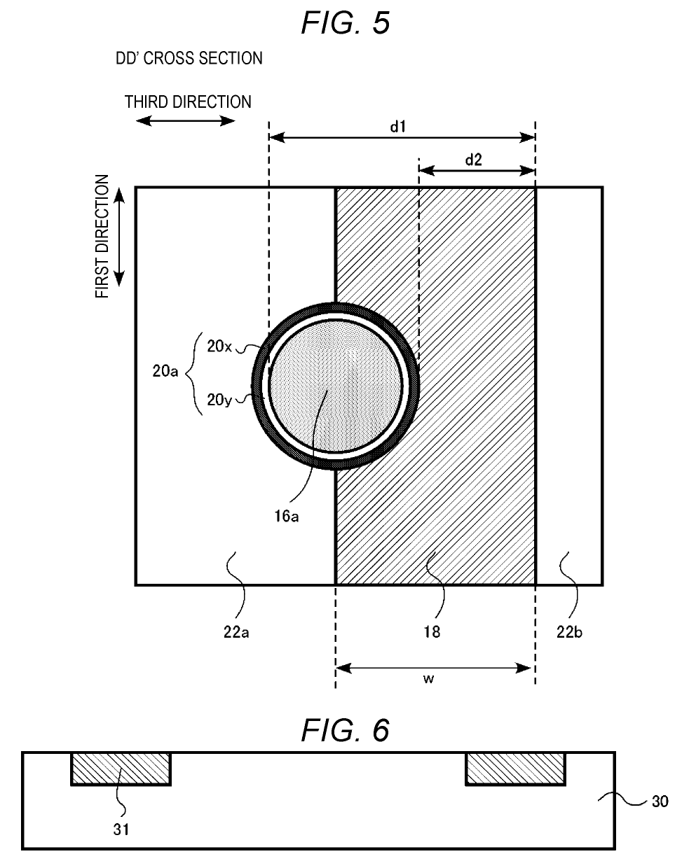

FIGS. 6, 7, 8, 9, 10, 11, 12, 13, 14, 15, 16, 17, 18, and 19 are schematic cross-sectional views showing an example of a method of manufacturing the semiconductor device according to the first embodiment. Each of FIGS. 6 to 19 shows a cross section corresponding in position to FIG. 1. Each of FIGS. 6 to 19 shows aspects of an example of a method of manufacturing the transistor 100.

Hereinafter, description will be given of a non-limiting example in which the lower electrode 12 of the transistor 100 is an indium tin oxide layer, the upper electrode 14 is an indium tin oxide layer, the oxide semiconductor layer 16 is an indium gallium zinc oxide layer, the gate electrode 18 is a tungsten layer, the gate insulating layer 20 is a stacked structure of a silicon nitride film and a silicon oxide film, the first wiring layer 21 is a tungsten layer, and the interlayer insulating layer 22 is a silicon oxide layer.

In this method, a first indium tin oxide layer 31 is formed in a first silicon oxide layer 30 (FIG. 6). The first silicon oxide layer 30 will eventually become the interlayer insulating layer 22. The first indium tin oxide layer 31 will eventually become the lower electrode 12.

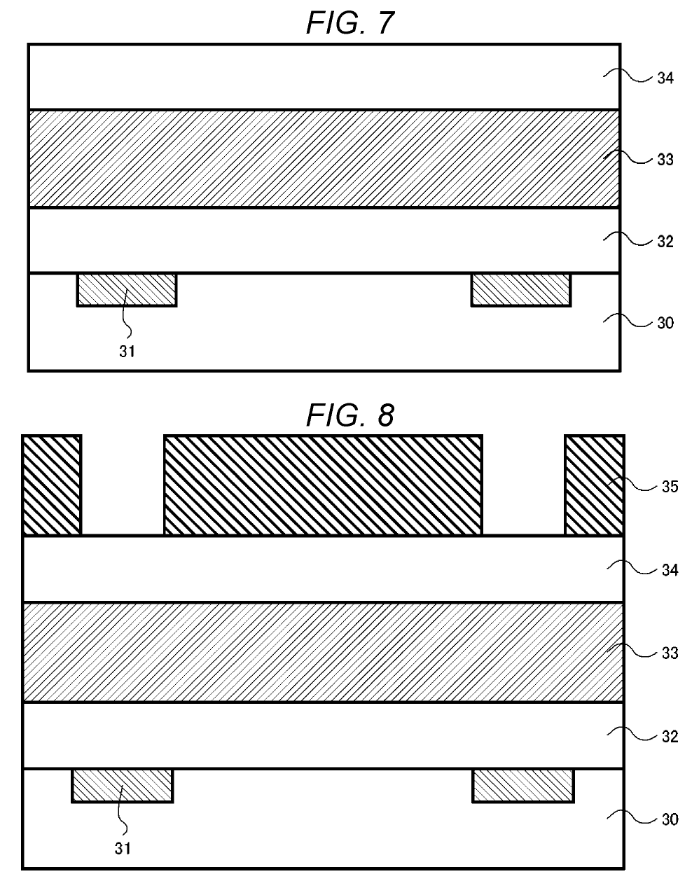

Next, a first silicon oxide film 32, a tungsten film 33, and a second silicon oxide film 34 are formed on the first silicon oxide layer 30 (FIG. 7). The first silicon oxide film 32, the tungsten film 33, and the second silicon oxide film 34 are formed, for example, by a chemical vapor deposition (CVD) method.

A part of the first silicon oxide film 32 and a part of the second silicon oxide film 34 will eventually become the interlayer insulating layer 22. A part of the tungsten film 33 will eventually become the gate electrode 18.

Next, a first mask material 35 is formed on the second silicon oxide film 34 (FIG. 8). The first mask material 35 is, for example, a photoresist.

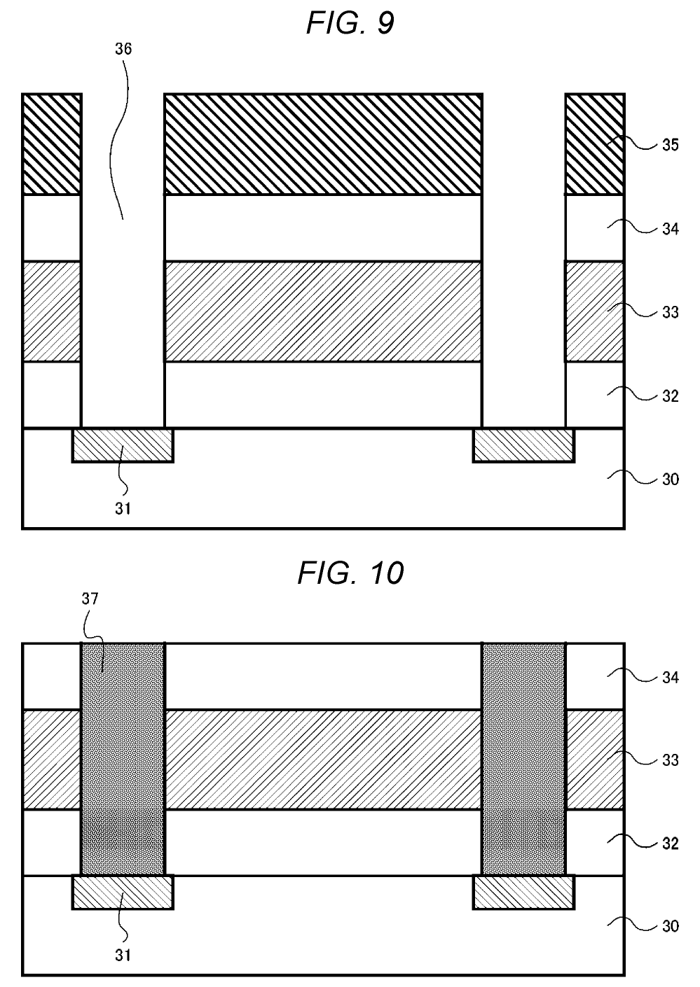

Next, the second silicon oxide film 34, the tungsten film 33, and the first silicon oxide film 32 are etched using the first mask material 35 as a mask to form a first opening 36 that reaches the first indium tin oxide layer 31 (FIG. 9). For the etching, a reactive ion etching (RIE) method can be used.

Next, the first mask material 35 is peeled off or otherwise removed, and the first opening 36 is filled with an amorphous silicon film 37 (FIG. 10). The amorphous silicon film 37 is formed, for example, by deposition using a CVD method followed by planarization using a chemical mechanical polishing method (CMP method).

Next, a second mask material 38 is formed on the second silicon oxide film 34 (FIG. 11). The second mask material 38 is, for example, a photoresist. The second mask material 38 is formed such that a part of the amorphous silicon film 37 is exposed and another part is covered.

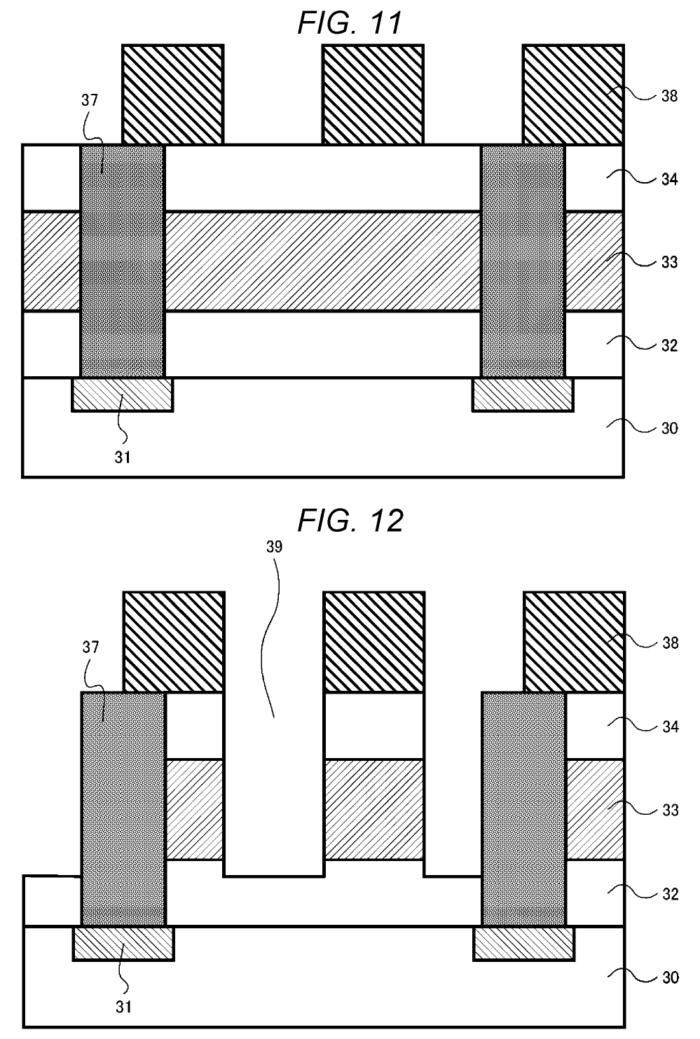

Next, the second silicon oxide film 34, the tungsten film 33, and the first silicon oxide film 32 are etched using the second mask material 38 as a mask to form a second opening 39 (FIG. 12). For example, an RIE method is used for etching.

In the etching, an etching condition capable of providing a high etching selectivity between silicon oxide and amorphous silicon is selected. By using a high etching selectivity between silicon oxide and amorphous silicon, etching of the amorphous silicon film 37 is curbed (limited).

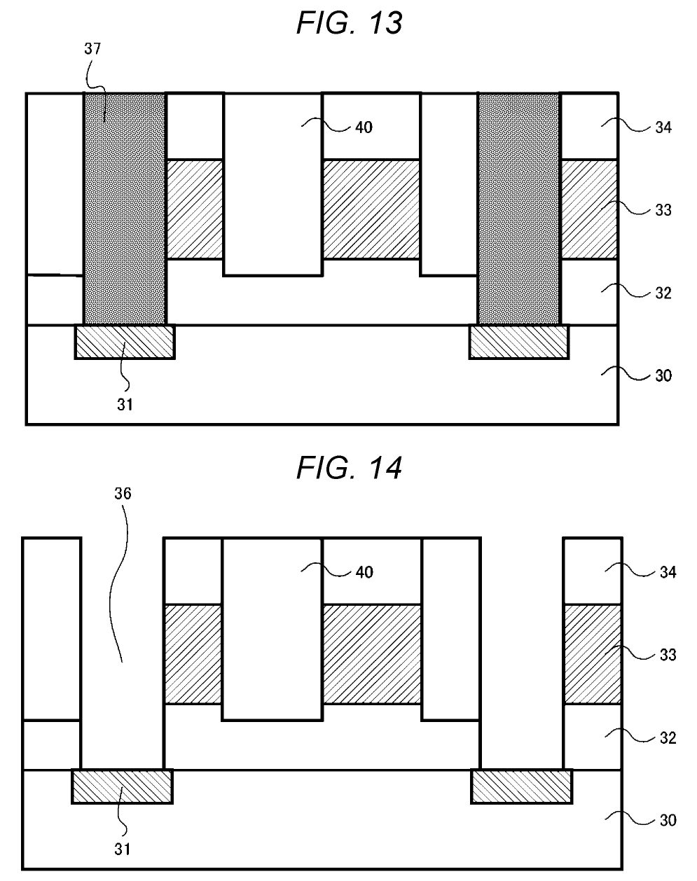

Next, the second mask material 38 is removed, and the second opening 39 is filled with a third silicon oxide film 40 (FIG. 13). The third silicon oxide film 40 is formed, for example, by deposition using a CVD method followed by planarization using a CMP method. The third silicon oxide film 40 will eventually become the interlayer insulating layer 22.

Next, the amorphous silicon film 37 filled in the first opening 36 is removed (FIG. 14). The amorphous silicon film 37 is removed, for example, by a wet etching method.

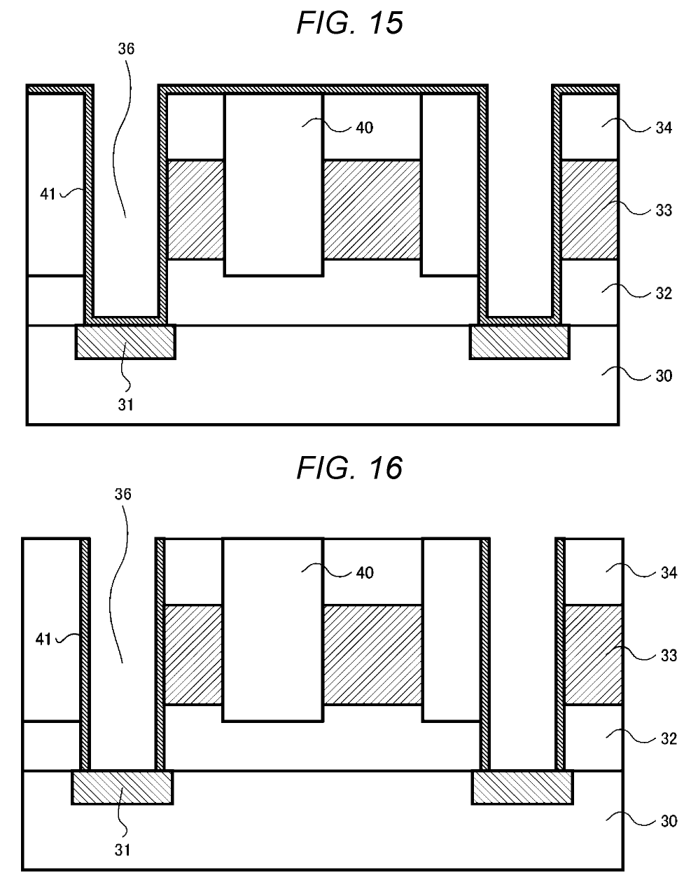

Next, a stacked film 41 of a silicon oxide film and a silicon nitride film is formed in the first opening 36 (FIG. 15). The stacked film 41 is formed, for example, by a CVD method. A part of the stacked film 41 will eventually become the gate insulating layer 20.

Next, the stacked film 41 at the bottom of the first opening 36 is removed to expose the first indium tin oxide layer 31 (FIG. 16). The stacked film 41 at the bottom of the first opening 36 is removed, for example, by an RIE method.

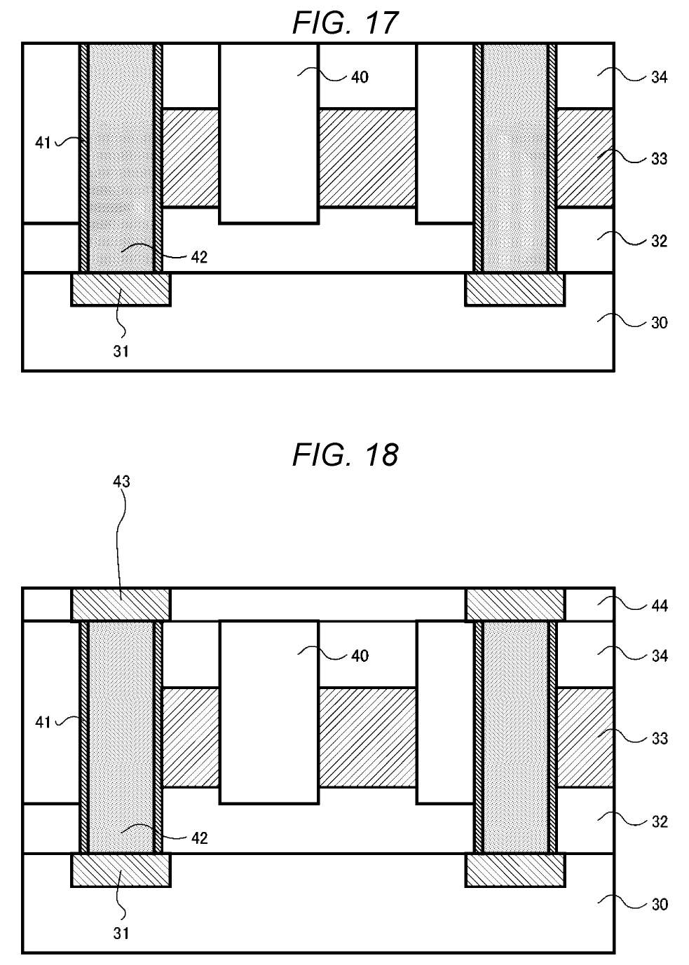

Next, the first opening 36 is filled with an indium gallium zinc oxide film 42 (FIG. 17). The indium gallium zinc oxide film 42 is formed, for example, by a CVD method, and then flattened by a CMP method.

Next, a second indium tin oxide layer 43 and a second silicon oxide layer 44 are formed using a conventional manufacturing method (FIG. 18). The second indium tin oxide layer 43 will eventually become the upper electrode 14. The second silicon oxide layer 44 will eventually become the interlayer insulating layer 22.

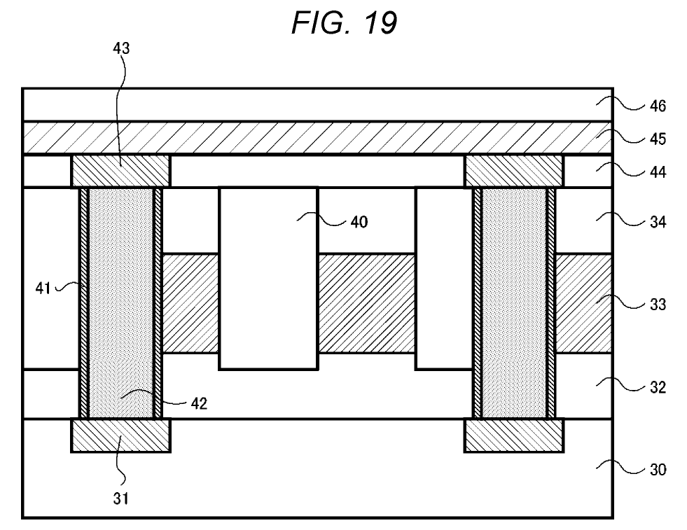

Next, a tungsten layer 45 and a third silicon oxide layer 46 are formed using a conventional manufacturing method (FIG. 19). The tungsten layer 45 will eventually become the first wiring layer 21. The third silicon oxide layer 46 will eventually become the interlayer insulating layer 22.

The transistor 100 shown in FIGS. 1 to 5 is manufactured by the above-described manufacturing method.

Next, certain operations and effects of the semiconductor device according to the first embodiment will be described.

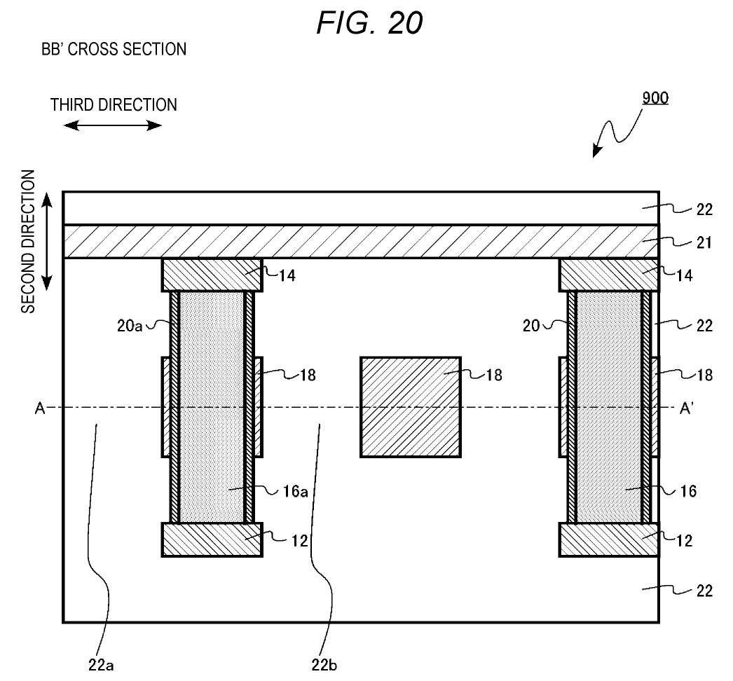

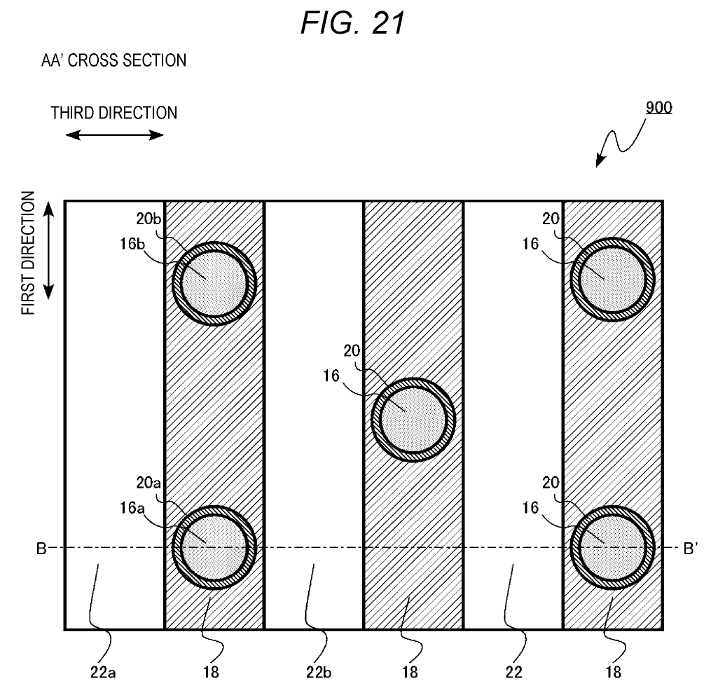

FIGS. 20 and 21 are schematic cross-sectional views of a semiconductor device according to a comparative example. FIG. 21 is a cross-sectional view taken along line AA' in FIG. 20. FIG. 20 is a cross-sectional view taken along line BB' in FIG. 21. FIG. 20 corresponds in position to FIG. 1 of the first embodiment. FIG. 21 corresponds in position to FIG. 3 of the first embodiment.

The semiconductor device according to the comparative example is a transistor 900. The transistor 900 differs from the transistor 100 according to the first embodiment in that, in a cross section perpendicular to the second direction and including the gate electrode 18, the gate insulating layer 20 is not in contact with the interlayer insulating layer 22. The transistor 900 differs from the transistor 100 in that, in a cross section perpendicular to the second direction, the gate insulating layer 20 is surrounded by the gate electrode 18.

In the transistor 900 according to the comparative example, the oxide semiconductor layer 16 penetrates the gate electrode 18. Since the oxide semiconductor layer 16 penetrates the gate electrode 18, an effective width of the gate electrode 18 in the third direction in the portion where the oxide semiconductor layer 16 exists (is present) becomes smaller. For this reason, the electrical resistance of the gate electrode 18 in the portion where the oxide semiconductor layer 16 exists becomes higher.

When the electrical resistance of the gate electrode 18 where the oxide semiconductor layer 16 exists becomes higher, the wiring resistance of the gate electrode 18 in the first direction increases. When the wiring resistance of the gate electrode 18 in the first direction becomes higher, a delay will occur in the operation of the transistor 900. Thus, for example, it becomes difficult to operate the transistor 900 at high speed.

For example, by reducing the width of the oxide semiconductor layer 16 in the third direction, it is possible to increase an effective width of the gate electrode 18 in the third direction in the portion where the oxide semiconductor layer 16 exists. However, reducing the width of the oxide semiconductor layer 16 in the third direction may make it difficult to form a pattern for the oxide semiconductor layer 16 having a small width when attempting to miniaturize the transistor 900. In addition, reducing the width of the oxide semiconductor layer 16 in the third direction may reduce the cross-sectional area of the channel of the transistor 900, which may increase the on resistance of the transistor 900.

In the transistor 100 according to the first embodiment, a part of the oxide semiconductor layer 16 is formed to protrude in the third direction beyond the gate electrode 18. In addition, a part of the gate insulating layer 20 is formed to protrude in the third direction beyond the gate electrode 18.

Thus, the transistor 100 can increase the effective width of the gate electrode 18 in the third direction in the portion where the oxide semiconductor layer 16 exists, as compared to that in the transistor 900. Thus, it is possible to increase the effective width of the gate electrode 18. Thus, for example, the transistor 100 can operate at high speed.

Further, in the transistor 100 according to the first embodiment, the gate insulating layer 20 is provided between the first portion 22a of the interlayer insulating layer 22 and the oxide semiconductor layer 16. The gate insulating layer 20 comprises at least one combination of elements selected from the group of combinations consisting of silicon (Si) and nitrogen (N), titanium (Ti) and oxygen (O), and aluminum (Al) and oxygen (O). By including one of the above combinations of elements, the gate insulating layer 20 can provide a good barrier against hydrogen (have a good hydrogen barrier property). By including one of the above combinations of elements, the gate insulating layer 20 can provide a better barrier against hydrogen as compared to a gate insulating layer formed of silicon oxide.

When there is no gate insulating layer 20 at all between the first portion 22a of the interlayer insulating layer 22 and the oxide semiconductor layer 16, or the gate insulating layer 20 does not contain any of the above-mentioned combinations of elements, it becomes difficult to curb the infiltration of hydrogen from the interlayer insulating layer 22 into the oxide semiconductor layer 16.

Hydrogen functions as a donor in the oxide semiconductor layer 16. Thus, the infiltration of hydrogen into the oxide semiconductor layer 16 may lower the threshold voltage of the transistor or degrade the cut-off characteristics of the transistor.

In the transistor 100, the gate insulating layer 20 is provided between the first portion 22a of the interlayer insulating layer 22 and the oxide semiconductor layer 16, and the gate insulating layer 20 also contains one of the above-mentioned combinations of elements, making it possible to curb the infiltration of hydrogen from the interlayer insulating layer 22 into the oxide semiconductor layer 16. Thus, it is possible to prevent a decrease in the threshold voltage and deterioration in the cut-off characteristics of the transistor 100.

From the viewpoint of reducing the electrical resistance of the gate electrode 18, a minimum distance (d2 in FIG. 5) between the first gate insulating layer 20a and an end of the gate electrode 18 on the second portion 22b side in the third direction is preferably one-third or more, more preferably one-half or more, of the maximum width (w in FIG. 5) of the gate electrode 18 in the third direction.

As described above, according to the first embodiment, the electrical resistance of the gate electrode can be reduced, and the infiltration of hydrogen into the oxide semiconductor layer is curbed. Thus, for example, a high-speed operation is possible, and a decrease in threshold voltage and deterioration of cut-off characteristics can be avoided. Thus, a semiconductor device with excellent transistor characteristics can be implemented.

### Second Embodiment

A semiconductor device according to a second embodiment differs from the semiconductor device according to the first embodiment in that, in a first cross section, a maximum distance in a third direction perpendicular to a first direction between an end of a first oxide semiconductor layer on a first portion side and an end of a gate electrode on a second portion side is smaller than a maximum width of the gate electrode in the third direction. In the following, some of the aspects that overlap with the first embodiment may be omitted from the description to focus on differences.

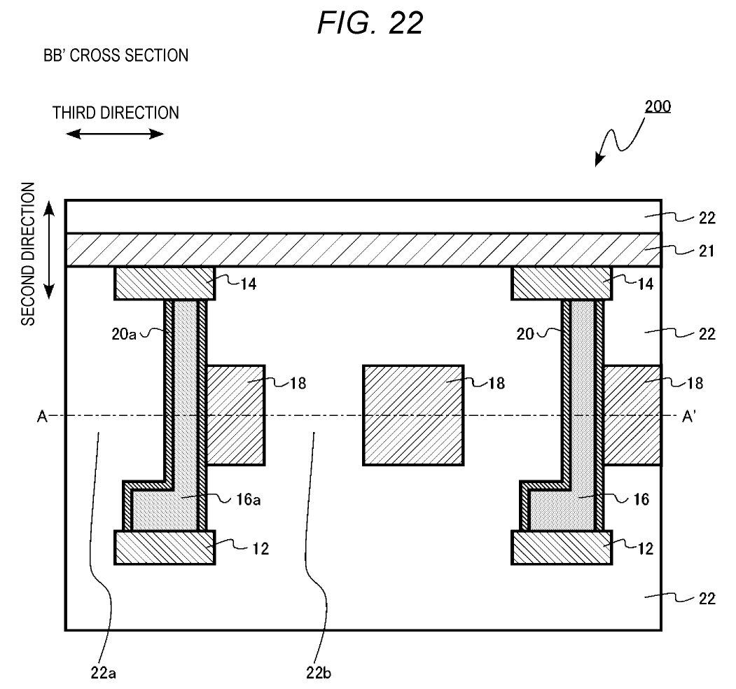

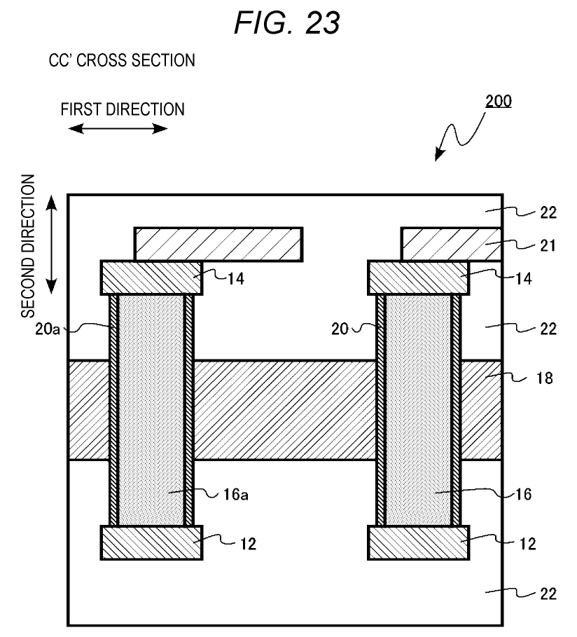

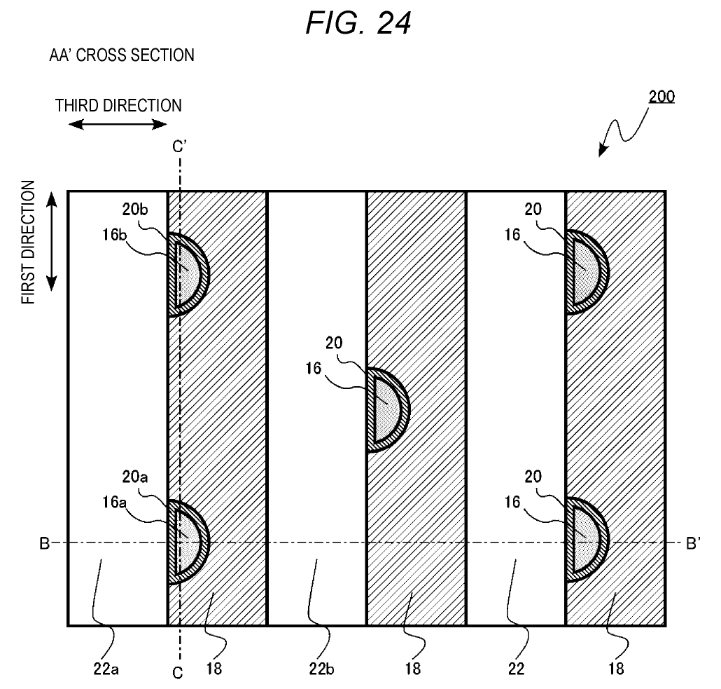

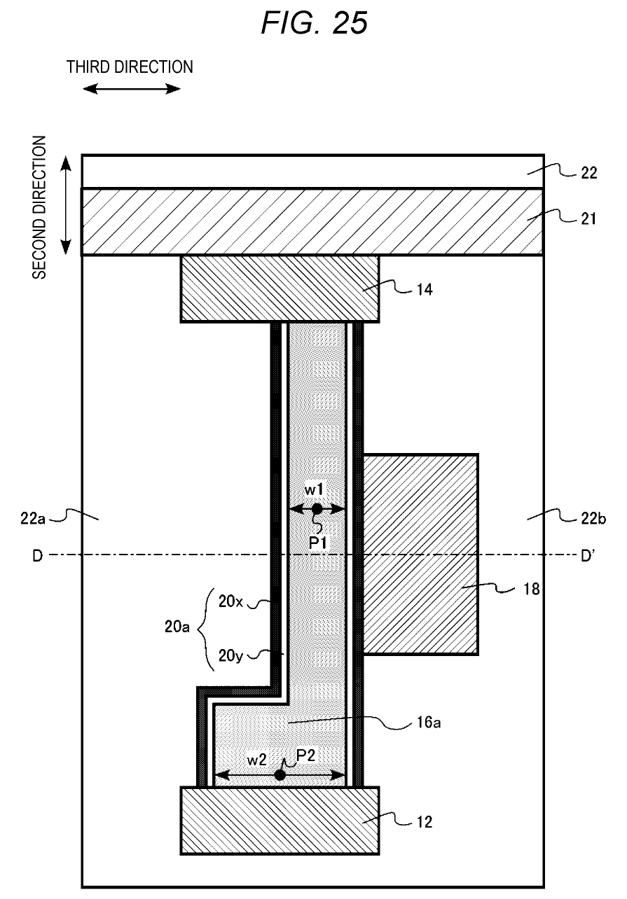

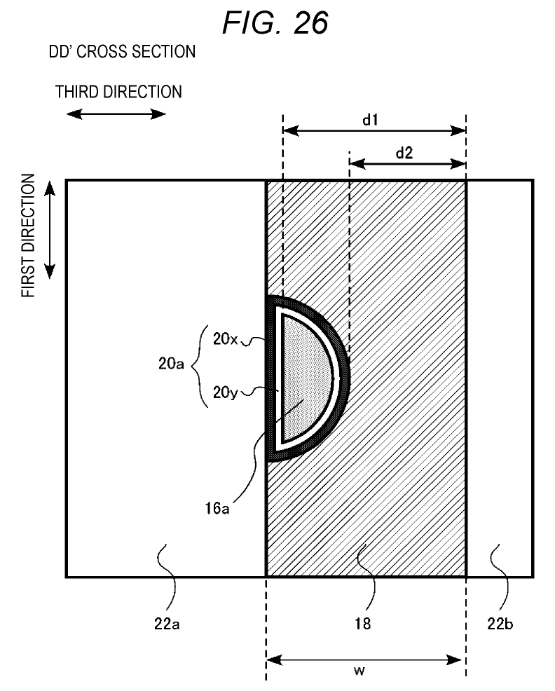

FIGS. 22, 23, and 24 are schematic cross-sectional views of the semiconductor device according to the second embodiment. FIG. 24 is a cross-sectional view taken along line AA' in FIG. 22. FIG. 22 is a cross-sectional view taken along line BB' in FIG. 24. FIG. 23 is a cross-sectional view taken along line CC' in FIG. 24.

FIGS. 22, 23, and 24 correspond to FIGS. 1, 2, and 3 of the first embodiment, respectively.

The semiconductor device according to the second embodiment is a transistor 200.

The transistor 200 includes a lower electrode 12, an upper electrode 14, an oxide semiconductor layer 16, a gate electrode 18, a gate insulating layer 20, a first wiring layer 21, and an interlayer insulating layer 22. The oxide semiconductor layer 16 includes a first oxide semiconductor layer 16a and a second oxide semiconductor layer 16b. The gate insulating layers 20 include a first gate insulating layer 20a and a second gate insulating layer 20b. The interlayer insulating layer 22 includes a first portion 22a and a second portion 22b.

As shown in FIG. 24, the oxide semiconductor layer 16 is semicircular in a cross section perpendicular to the second direction and including the gate electrode 18. The first oxide semiconductor layer 16a and the second oxide semiconductor layer 16b are semicircular in a cross section perpendicular to the second direction and including the gate electrode 18.

FIGS. 25 and 26 are enlarged schematic cross-sectional views of the semiconductor device according to the second embodiment. FIG. 25 is an enlarged cross-sectional view of a portion of FIG. 22. FIG. 26 is an enlarged cross-sectional view of a portion of FIG. 24. FIG. 26 is a cross-sectional view taken along line DD' in FIG. 25.

FIGS. 25 and 26 correspond to FIGS. 4 and 5 of the first embodiment, respectively.

As shown in FIG. 25, the width (w1 in FIG. 25) of a portion between the first portion 22a and the second portion 22b of the first oxide semiconductor layer 16a in the third direction is smaller than the width (w2 in FIG. 25) of a portion of the first oxide semiconductor layer 16a which is in contact with the lower electrode 12 in the third direction. The width w1 of the portion between the first portion 22a and the second portion 22b of the first oxide semiconductor layer 16a in the third direction is, for example, two-thirds or less of the width w2 of the portion of the first oxide semiconductor layer 16a which is in contact with the lower electrode 12 in the third direction.

As shown in FIG. 25, a center (middle) position (P1 in FIG. 25) along the third direction at a position between the first portion 22a and the second portion 22b is shifted in the third direction from a center position (P2 in FIG. 25) for the portion of the first oxide semiconductor layer 16a which is in contact with the lower electrode 12.

As shown in FIG. 26, in a cross section perpendicular to the second direction and including the gate electrode 18, the shape of the first oxide semiconductor layer 16a is semicircular. The first oxide semiconductor layer 16a does not protrude in the third direction with respect to the gate electrode 18. In addition, a part of the first gate insulating layer 20a does not protrude in the third direction beyond the edge of gate electrode 18.

As shown in FIG. 26, a maximum distance (d1 in FIG. 26) between an end of the first oxide semiconductor layer 16a on the first portion 22a side and an end of the gate electrode 18 on the second portion 22b side in the third direction is smaller than a maximum width (w in FIG. 26) of the gate electrode 18 in the third direction.

As shown in FIG. 26, a minimum distance (d2 in FIG. 26) between the first gate insulating layer 20a and the end of the gate electrode 18 on the second portion 22b side in the third direction is, for example, one-third or more of the maximum width (w in FIG. 26) of the gate electrode 18 in the third direction.

As shown in FIG. 26, a part of the first gate insulating layer 20a is in contact with the gate electrode 18. Another part of the first gate insulating layer 20a is in contact with the first portion 22a of the interlayer insulating layer 22.

Next, an example of a method of manufacturing the semiconductor device according to the second embodiment will be described.

FIGS. 27, 28, 29, 30, 31, 32, 33, 34, and 35 are schematic cross-sectional views showing aspects of a method of manufacturing the semiconductor device according to the second embodiment. FIGS. 27 to 35 show an example of a method of manufacturing the transistor 200.

Hereinafter, description will be given of an example in which the lower electrode 12 of the transistor 200 is an indium tin oxide layer, the upper electrode 14 is an indium tin oxide layer, the oxide semiconductor layer 16 is an indium gallium zinc oxide layer, the gate electrode 18 is a tungsten layer, the gate insulating layer 20 is a stacked structure of a silicon nitride film and a silicon oxide film, the first wiring layer 21 is a tungsten layer, and the interlayer insulating layer 22 is a silicon oxide layer.

The manufacturing method is the same as that in the first embodiment up to the formation of a second mask material 38 on a second silicon oxide film 34 (FIG. 27). The second mask material 38 is, for example, a photoresist. The second mask material 38 is formed to expose a part of an amorphous silicon film 37 and cover another part.

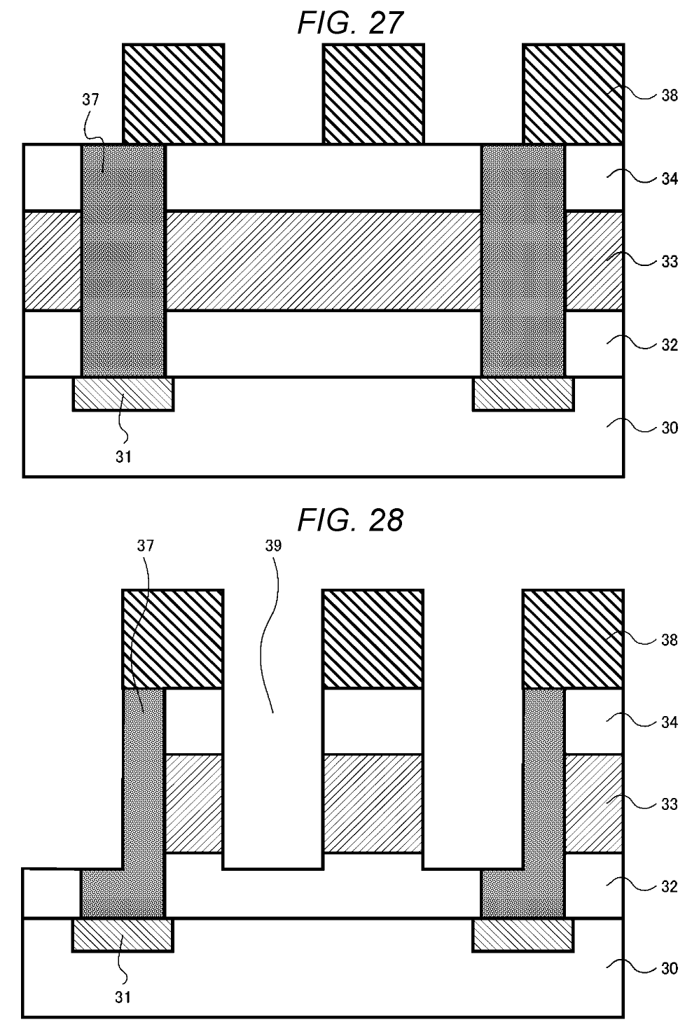

Next, a second silicon oxide film 34, a tungsten film 33, a first silicon oxide film 32, and the amorphous silicon film 37 are etched using the second mask material 38 as a mask to form a second opening 39 (FIG. 28). For example, an RIE method is used for the etching.

In the etching, an etching condition that provides a low etching selectivity between silicon oxide and amorphous silicon can be selected. The low etching selectivity between silicon oxide and amorphous silicon means the amorphous silicon film 37 will also be etched in this processing.

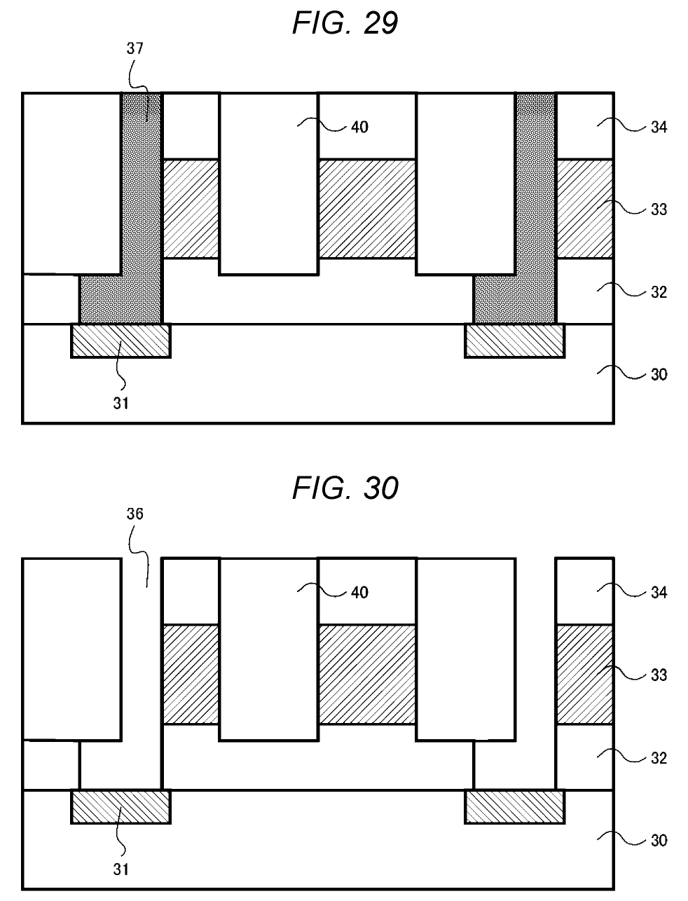

Next, the second mask material 38 is peeled off or otherwise removed, and the second opening 39 is filled with a third silicon oxide film 40 (FIG. 29). The third silicon oxide film 40 is formed, for example, by deposition using a CVD method followed by planarization using a CMP method. The third silicon oxide film 40 will eventually become the interlayer insulating layer 22.

Next, the amorphous silicon film 37 is removed from a first opening 36 (FIG. 30). The amorphous silicon film 37 is removed, for example, by a wet etching method.

Next, a stacked film 41 of a silicon oxide film and a silicon nitride film is formed on the sidewalls of the first opening 36 (FIG. 31). A part of the stacked film 41 will eventually become the gate insulating layer 20.

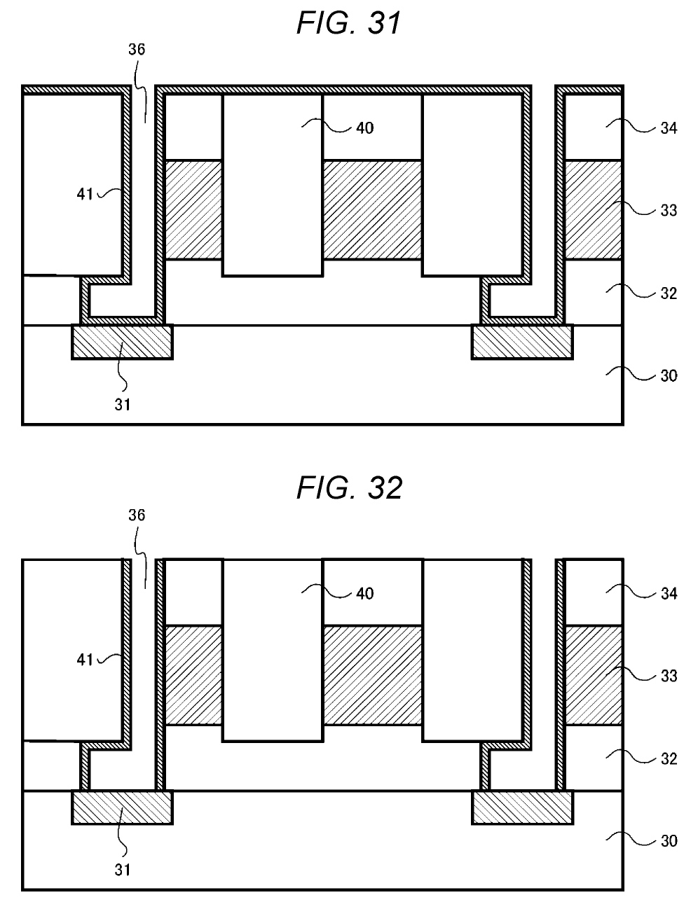

Next, the stacked film 41 at the bottom of the first opening 36 is removed to expose the first indium tin oxide layer 31 (FIG. 32).

Next, the first opening 36 is filled with an indium gallium zinc oxide film 42 (FIG. 33). The indium gallium zinc oxide film 42 is formed using, for example, a CVD method and then planarized using a CMP method.

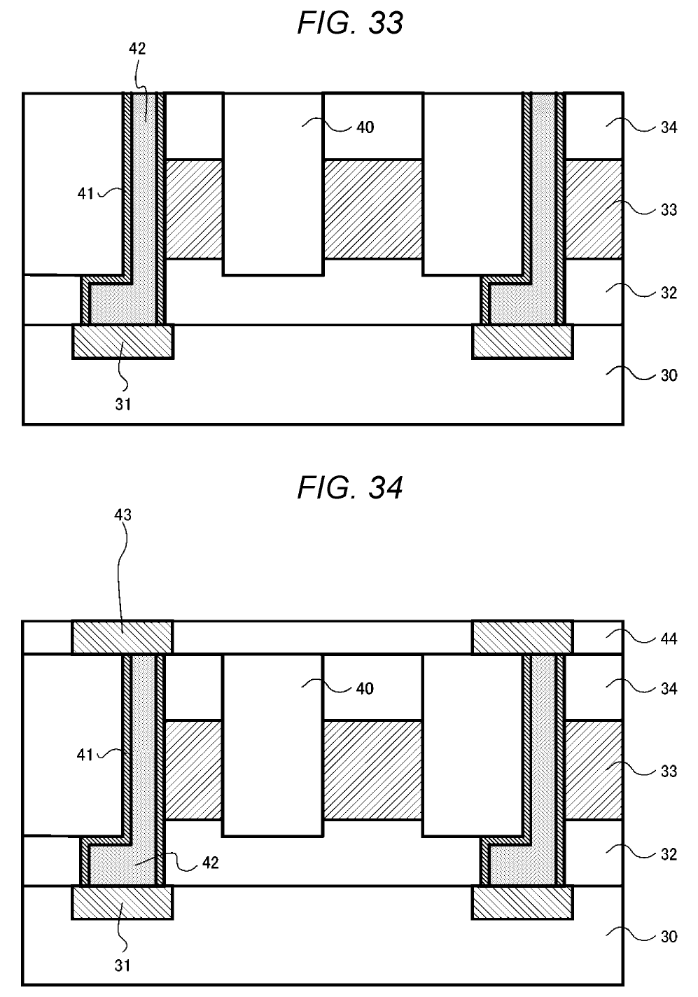

Next, a second indium tin oxide layer 43 and a second silicon oxide layer 44 are formed using a conventional manufacturing method (FIG. 34). The second indium tin oxide layer 43 will eventually become the upper electrode 14. The second silicon oxide layer 44 will eventually become the interlayer insulating layer 22.

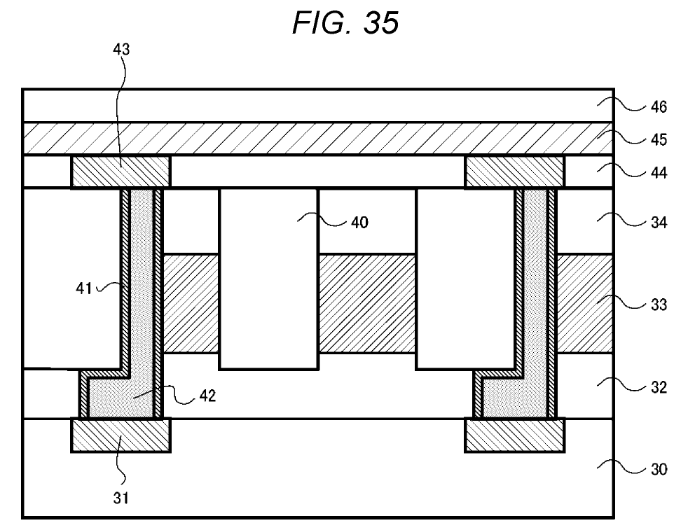

Next, a tungsten layer 45 and a third silicon oxide layer 46 are formed using a conventional manufacturing method (FIG. 35). The tungsten layer 45 will eventually become the first wiring layer 21. The third silicon oxide layer 46 will eventually become the interlayer insulating layer 22.

The transistor 200 shown in FIGS. 22 to 26 is manufactured by the above manufacturing method.

The transistor 200 according to the second embodiment can increase an effective width of the gate electrode 18 in the third direction in a portion where the oxide semiconductor layer 16 exists, similar to the transistor 100 according to the first embodiment. Thus, for example, the transistor 200 can operate at high speed.

In addition, similarly to the transistor 100 according to the first embodiment, in the transistor 200 according to the second embodiment, the gate insulating layer 20 is provided between the first portion 22a of the interlayer insulating layer 22 and the oxide semiconductor layer 16, and the gate insulating layer 20 also contains combination of elements described for the first embodiment, which makes it possible to curb the infiltration of hydrogen from the interlayer insulating layer 22 into the oxide semiconductor layer 16. Thus, it is possible to avoid a decrease in the threshold voltage and the deterioration of the cut-off characteristics of the transistor 200.

Further, in the transistor 200, as shown in FIG. 26, the first oxide semiconductor layer 16a does not protrude in the third direction beyond the gate electrode 18. Thus, compared to the transistor 100 according to the first embodiment, the controllability of an electric field in the first oxide semiconductor layer 16a by the gate electrode 18 is improved. Thus, for example, it is possible to further curb a decrease in threshold voltage and deterioration of cut-off characteristics.

From the viewpoint of reducing the electrical resistance of the gate electrode 18 in the portion where the oxide semiconductor layer 16 exists, the minimum distance (d2 in FIG. 26) between the first gate insulating layer 20a and an end of the gate electrode 18 on the second portion 22b side in the third direction is preferably one-third or more, more preferably one-half or more, of the maximum width (w in FIG. 26) of the gate electrode 18 in the third direction.

As described above, according to the semiconductor device in the second embodiment, the electrical resistance of the gate electrode is reduced, and the infiltration of hydrogen into the oxide semiconductor layer is curbed. Thus, for example, a high-speed operation is possible, and a decrease in threshold voltage and deterioration of cut-off characteristics can be curbed. Thus, a semiconductor device with excellent transistor characteristics can be implemented.

### Third Embodiment

A semiconductor device according to a third embodiment differs from the semiconductor device according to the first embodiment in that it further includes a third oxide semiconductor layer that is located between a first oxide semiconductor layer and a second oxide semiconductor layer in a first direction, and a third gate insulating layer that is provided between a gate electrode and the third oxide semiconductor layer, surrounds the third oxide semiconductor layer, contains at least one combination of elements, and is in contact with a second portion in a first cross section. Hereinafter, some of the aspects that overlap with the first embodiment may be omitted.

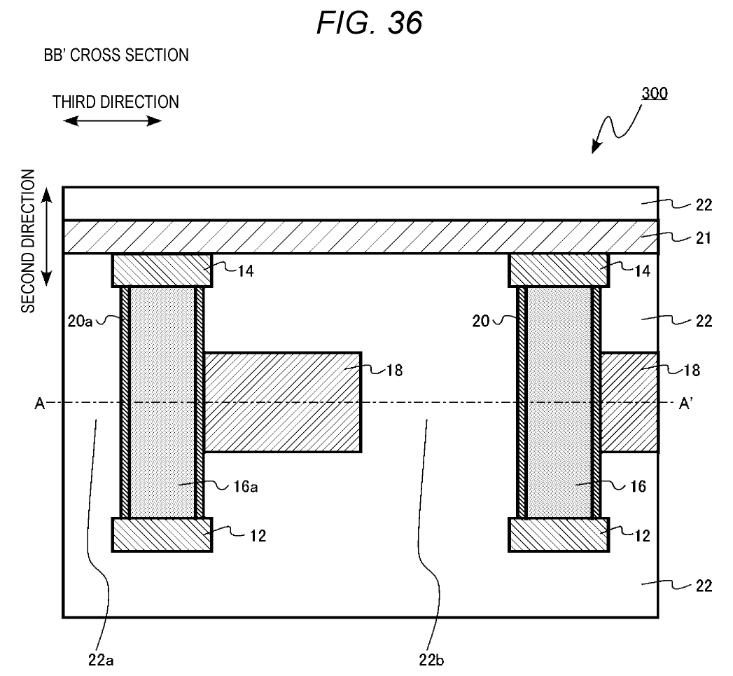

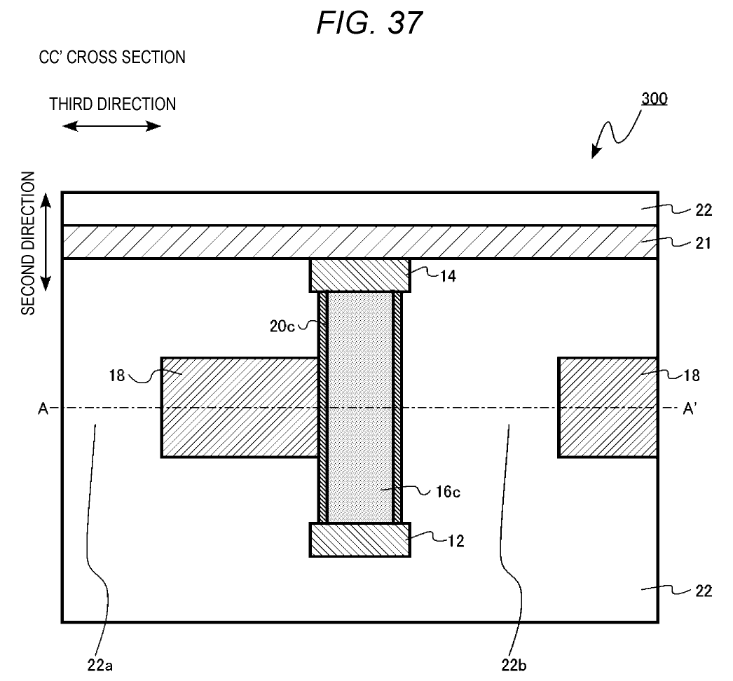

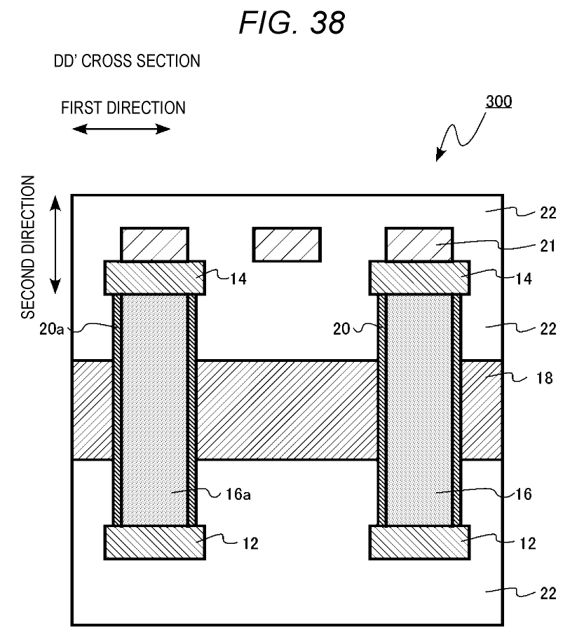

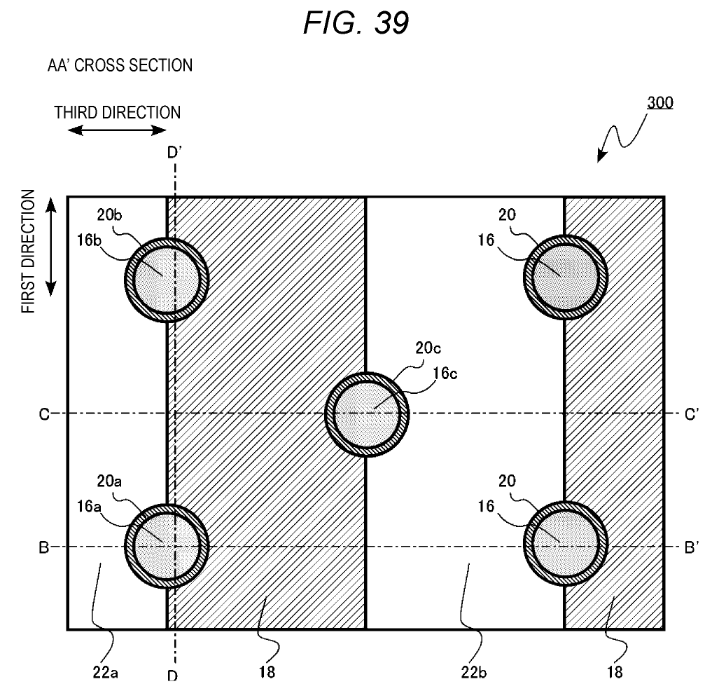

FIGS. 36, 37, 38, and 39 are schematic cross-sectional views of the semiconductor device according to the third embodiment. FIG. 39 is a cross-sectional view taken along line AA' in FIGS. 36 and 37. FIG. 36 is a cross-sectional view taken along line BB' in FIG. 39. FIG. 37 is a cross-sectional view taken along line CC' in FIG. 39. FIG. 38 is a cross-sectional view taken along line DD' in FIG. 39.

FIGS. 36, 38, and 39 correspond to FIGS. 1, 2, and 3 of the first embodiment, respectively.

The semiconductor device according to the third embodiment is a transistor 300.

The transistor 300 includes a lower electrode 12, an upper electrode 14, an oxide semiconductor layer 16, a gate electrode 18, a gate insulating layer 20, a first wiring layer 21, and an interlayer insulating layer 22. The oxide semiconductor layer 16 includes a first oxide semiconductor layer 16a, a second oxide semiconductor layer 16b, and a third oxide semiconductor layer 16c. The gate insulating layers 20 include a first gate insulating layer 20a, a second gate insulating layer 20b, and a third gate insulating layer 20c. The interlayer insulating layer 22 includes a first portion 22a and a second portion 22b.

As shown in FIG. 39, the second oxide semiconductor layer 16b is provided in a first direction of the first oxide semiconductor layer 16a. As shown in FIG. 39, the position of the third oxide semiconductor layer 16c in the first direction is between the position of the first oxide semiconductor layer 16a in the first direction and the position of the second oxide semiconductor layer 16b in the first direction.

The first oxide semiconductor layer 16a and the second oxide semiconductor layer 16b are provided on the first portion 22a side of the gate electrode 18. The third oxide semiconductor layer 16c is provided on the second portion 22b side of the gate electrode 18.

The first gate insulating layer 20a is provided between the first oxide semiconductor layer 16a and the gate electrode 18. The first gate insulating layer 20a surrounds the first oxide semiconductor layer 16a. The second gate insulating layer 20b is provided between the second oxide semiconductor layer 16b and the gate electrode 18. The second gate insulating layer 20b surrounds the second oxide semiconductor layer 16b. The third gate insulating layer 20c is provided between the third oxide semiconductor layer 16c and the gate electrode 18. The third gate insulating layer 20c surrounds the third oxide semiconductor layer 16c.

In a cross section perpendicular to the second direction and including the gate electrode 18, a part of the first gate insulating layer 20a is in contact with the gate electrode 18. In a cross section perpendicular to the second direction and including the gate electrode 18, another part of the first gate insulating layer 20a is in contact with the first portion 22a of the interlayer insulating layer 22.

In a cross section perpendicular to the second direction and including the gate electrode 18, a part of the second gate insulating layer 20b is in contact with the gate electrode 18. In a cross section perpendicular to the second direction and including the gate electrode 18, another part of the second gate insulating layer 20b is in contact with the first portion 22a of the interlayer insulating layer 22.

In a cross section perpendicular to the second direction and including the gate electrode 18, a part of the third gate insulating layer 20c is in contact with the gate electrode 18. In a cross section perpendicular to the second direction and including the gate electrode 18, another part of the third gate insulating layer 20c is in contact with the second portion 22b of the interlayer insulating layer 22.

As shown in FIG. 39, in a cross section perpendicular to the second direction and including the gate electrode 18, the shape of the first oxide semiconductor layer 16a is circular. A part of the first oxide semiconductor layer 16a protrudes in the third direction beyond the gate electrode 18 outer edge. A part of the first oxide semiconductor layer 16a protrudes outward toward the first portion 22a side from the gate electrode 18 outer edge. The first gate insulating layer 20a also protrudes outward toward the first portion 22a side.

As shown in FIG. 39, the shape of the third oxide semiconductor layer 16c is circular in cross-section perpendicular to the second direction. A part of the third oxide semiconductor layer 16c protrudes in the third direction beyond the gate electrode 18 outer edge. A part of the third oxide semiconductor layer 16c protrudes toward the second portion 22b side from the gate electrode 18. In addition, the third gate insulating layer 20c also protrudes toward the second portion 22b side.

In the transistor 300 according to the third embodiment, an oxide semiconductor layer 16 is disposed on both sides (edges) of the gate electrode 18. By providing the oxide semiconductor layer 16 on both sides of the gate electrode 18, a pitch of the gate electrodes 18 in the third direction can be, for example, twice that of the transistor 100 according to the first embodiment. Thus, the width of the gate electrode 18 in the third direction is increased, and the wiring resistance of the gate electrode 18 in the first direction can be further reduced. Thus, for example, the transistor 300 can operate at high speed.

As described above, according to the semiconductor device in the third embodiment, the electrical resistance of the gate electrode is reduced, and the infiltration of hydrogen into the oxide semiconductor layer is curbed. Thus, for example, a high-speed operation is possible, and a decrease in threshold voltage and deterioration of cut-off characteristics can be curbed. Thus, a semiconductor device with excellent transistor characteristics can be implemented.

### Fourth Embodiment

A semiconductor device according to a fourth embodiment differs from the semiconductor device according to the third embodiment in that an oxide semiconductor layer is semicircular in a cross section. In the following, some of the aspects that overlap with the previous embodiments may be omitted.

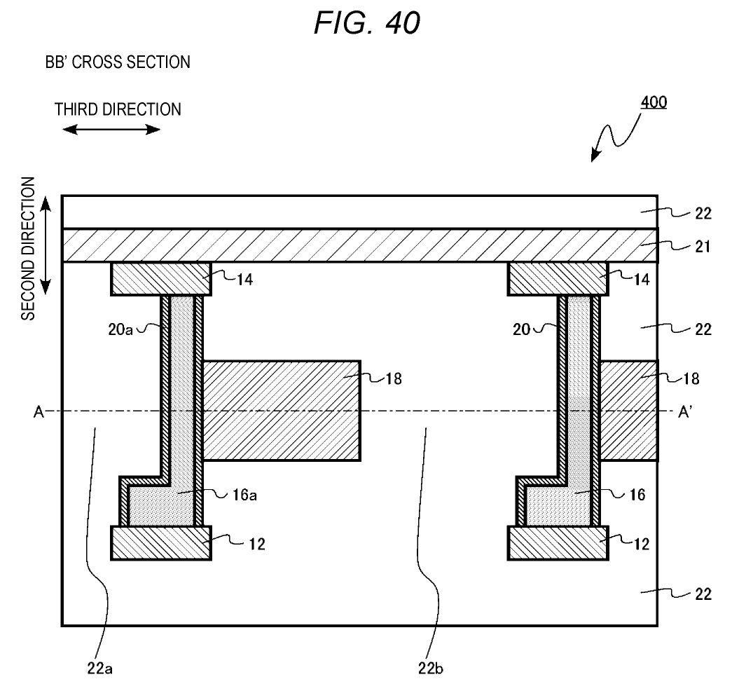

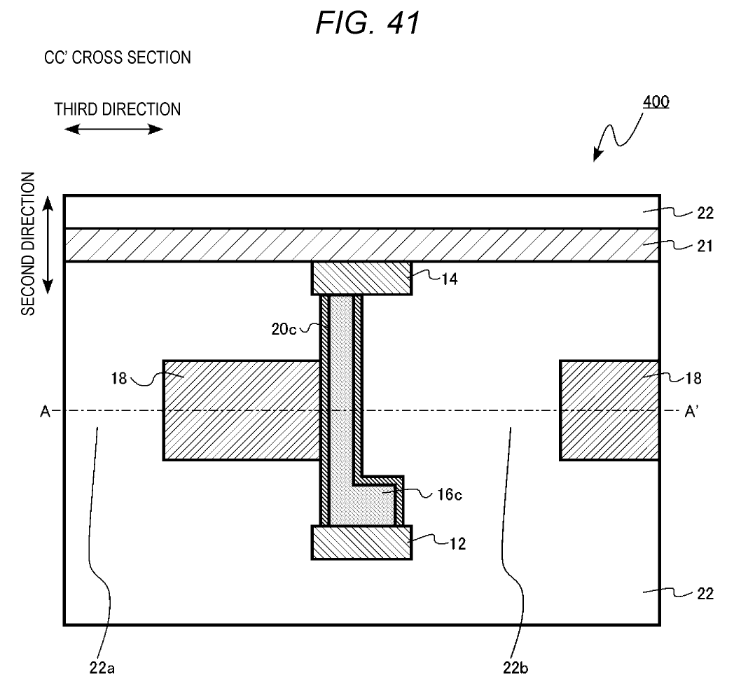

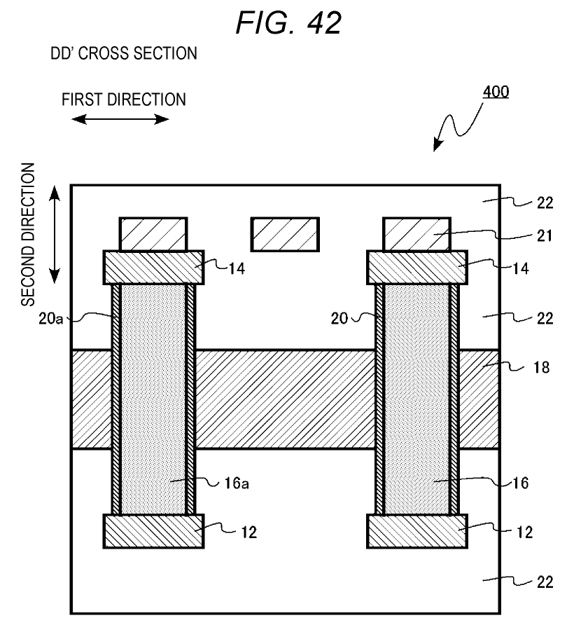

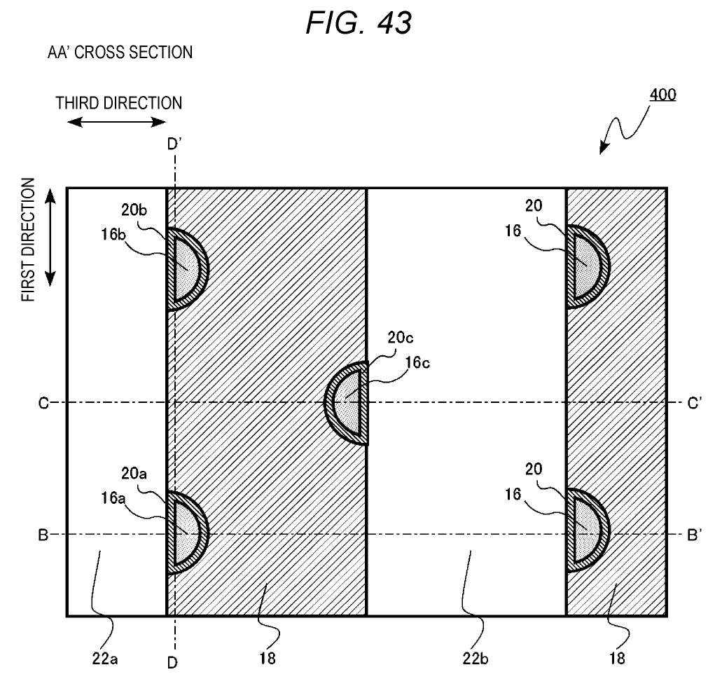

FIGS. 40, 41, 42, and 43 are schematic cross-sectional views of the semiconductor device according to the fourth embodiment. FIG. 43 is a cross-sectional view taken along line AA' in FIGS. 40 and 41. FIG. 40 is a cross-sectional view taken along line BB' in FIG. 43. FIG. 41 is a cross-sectional view taken along line CC' in FIG. 43. FIG. 42 is a cross-sectional view taken along line DD' in FIG. 43.

FIGS. 40, 41, 42, and 43 correspond to FIGS. 36, 37, 38, and 39 of the third embodiment, respectively.

The semiconductor device according to the fourth embodiment is a transistor 400.

The transistor 400 includes a lower electrode 12, an upper electrode 14, an oxide semiconductor layer 16, a gate electrode 18, a gate insulating layer 20, a first wiring layer 21, and an interlayer insulating layer 22. The oxide semiconductor layer 16 includes a first oxide semiconductor layer 16a, a second oxide semiconductor layer 16b, and a third oxide semiconductor layer 16c. The gate insulating layers 20 include a first gate insulating layer 20a, a second gate insulating layer 20b, and a third gate insulating layer 20c. The interlayer insulating layer 22 includes a first portion 22a and a second portion 22b.

As shown in FIG. 43, in a cross section perpendicular to the second direction and including the gate electrode 18, the shape of the first oxide semiconductor layer 16a is semicircular. The first oxide semiconductor layer 16a does not protrude in the third direction beyond the gate electrode 18. In addition, the first gate insulating layer 20a also does not protrude in the third direction with respect to the gate electrode 18.

As shown in FIG. 43, the shape of the third oxide semiconductor layer 16c is semicircular. The third oxide semiconductor layer 16c does not protrude in the third direction beyond the gate electrode 18. The third gate insulating layer 20c also does not protrude in the third direction with respect to the gate electrode 18.

As described above, according to the semiconductor device in the fourth embodiment, the electrical resistance of the gate electrode is reduced, and the infiltration of hydrogen into the oxide semiconductor layer is curbed. Thus, for example, a high-speed operation is possible, and a decrease in threshold voltage and deterioration of cut-off characteristics can be curbed. Thus, a semiconductor device with excellent transistor characteristics can be implemented.

### Fifth Embodiment

A semiconductor memory device according to a fifth embodiment includes a semiconductor device according to the first embodiment and a capacitor electrically connected to either a first electrode or a second electrode thereof.

The semiconductor memory device according to the fifth embodiment is a semiconductor memory 500. The semiconductor memory device according to the fifth embodiment can be a DRAM. The semiconductor memory 500 uses the transistor 100 according to the first embodiment as a switching transistor of a memory cell in the DRAM.

In the following, some of the aspects that overlap with the first embodiment will be omitted.

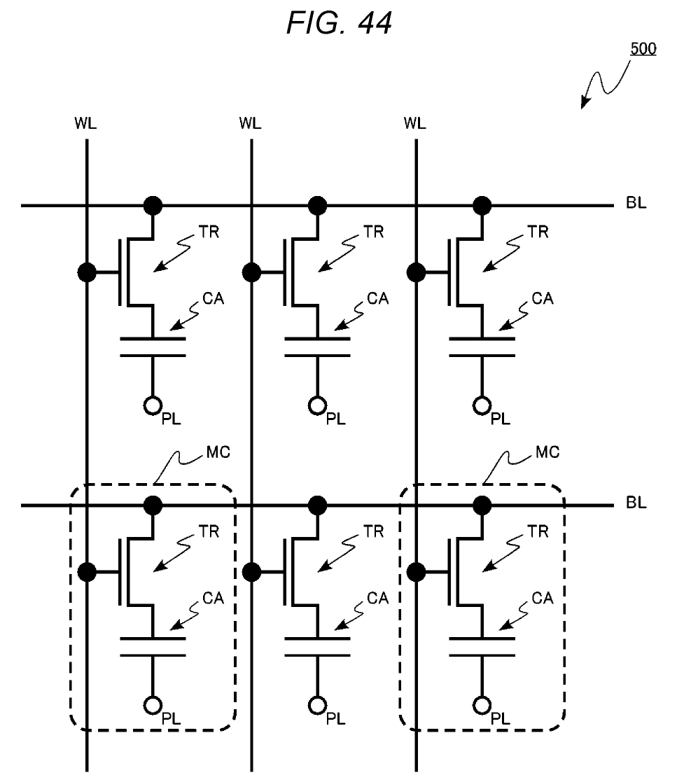

FIG. 44 is an equivalent circuit diagram of the semiconductor memory device according to the fifth embodiment. Although FIG. 44 shows an example of a case where there are six memory cells MC, the number of memory cells MC is not particularly limited and can be more than six, for example.

The semiconductor memory 500 includes a memory cell MC, word lines WL, bit lines BL, and plate lines PL. The memory cell MC includes a switching transistor TR and a capacitor CA. In FIG. 44, a region surrounded by a dashed line can be considered to correspond to the memory cell MC.

The word line WL is electrically connected to a gate electrode of the switching transistor TR. The bit line BL is electrically connected to one of source and drain electrodes of the switching transistor TR. One electrode of the capacitor CA is electrically connected to the other of the source and drain electrodes of the switching transistor TR. The other electrode of the capacitor CA is connected to the plate line PL.

The memory cell MC stores data by storing charges in the capacitor CA. Data is written and read by turning on the switching transistor TR.

For example, the switching transistor TR is turned on in a state where a desired voltage is applied to the bit line BL, and data can be written to the memory cell MC.

In addition, the switching transistor TR is turned on, a change in the voltage of the bit line BL corresponding to the amount of charges stored in the capacitor is detected, and data in the memory cell MC can be read.

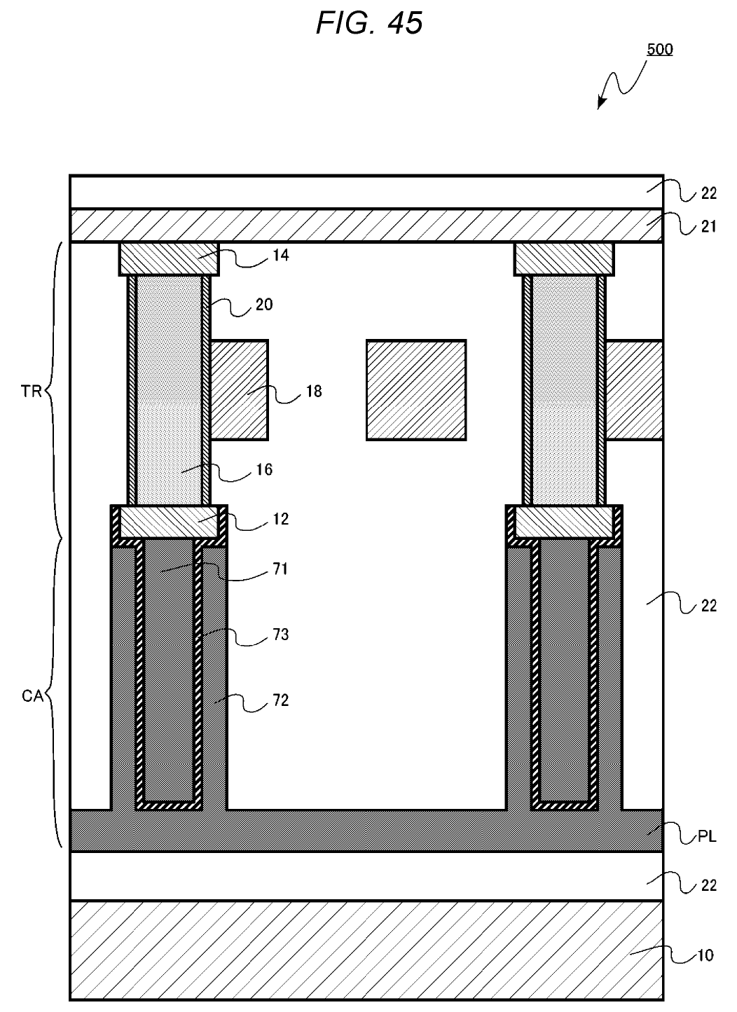

FIG. 45 is a schematic cross-sectional view of the semiconductor memory device according to the fifth embodiment. FIG. 45 shows the cross section of the memory cell MC of the semiconductor memory 500. FIG. 45 shows the cross section of two switching transistors TR connected to the same bit line BL surrounded by a dashed line in FIG. 44.

The semiconductor memory 500 includes a silicon substrate 10, the switching transistor TR, the capacitor CA, and an interlayer insulating layer 22.

The switching transistor TR includes a lower electrode 12, an upper electrode 14, an oxide semiconductor layer 16, a gate electrode 18, and a gate insulating layer 20.

The switching transistor TR thus has a structure similar to that of the transistor 100 according to the first embodiment.

The capacitor CA is provided between the silicon substrate 10 and the switching transistor TR. The capacitor CA is provided between the silicon substrate 10 and the lower electrode 12. The capacitor CA is electrically connected to the lower electrode 12.

The capacitor CA includes a cell electrode 71, a plate electrode 72, and a capacitor insulating film 73. The cell electrode 71 is electrically connected to the lower electrode 12. The cell electrode 71 is in contact with, for example, the lower electrode 12.

The cell electrode 71 and the plate electrode 72 are, for example, titanium nitride. The capacitor insulating film 73 has a stacked structure of, for example, zirconium oxide, aluminum oxide, and zirconium oxide.

The gate electrode 18 is the word line WL. The upper electrode 14 is electrically connected to a first wiring layer 21. The first wiring layer 21 is the bit line BL. The plate electrode 72 is connected to the plate line PL.

In the semiconductor memory 500, an oxide semiconductor transistor with an extremely small channel leakage current during a turn-off operation is used as the switching transistor TR. Thus, a DRAM with excellent charge retention characteristics is implemented.

In the fifth embodiment, a case where the capacitor CA is electrically connected to the lower electrode 12 is described as an example, but the capacitor CA may be electrically connected to the upper electrode 14.

In the fifth embodiment, the semiconductor memory to which a transistor according to the first embodiment is applied is described as an example, but the semiconductor memory in other example embodiments may use a transistor according to any of the second to fourth embodiments.

In the switching transistor TR of the semiconductor memory 500, the electrical resistance of the gate electrode is reduced, and the infiltration of hydrogen into the oxide semiconductor layer is curbed. Thus, the switching transistor TR can operate at high speed, and a decrease in threshold voltage and deterioration of cut-off characteristics can be curbed. Thus, according to the semiconductor memory device in the fifth embodiment, a semiconductor memory device with excellent transistor characteristics can be implemented.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. For example, a component of one embodiment may be replaced with a component of another embodiment or changed. The accompanying claims and their equivalents are intended to cover such forms or modifications as would fall within the scope and spirit of the disclosure.

What is claimed is:

1. A semiconductor device, comprising:
a first electrode;
a second electrode;
a gate electrode extending in a first direction;
a first oxide semiconductor layer extending in a second direction through a portion of the gate electrode, the first oxide semiconductor layer extending in the second direction between the first electrode and the second electrode, the gate electrode facing the first oxide semiconductor layer at a position between the first and second electrodes in the second direction;
a first gate insulating layer surrounding the first oxide semiconductor layer, the first gate insulating layer being between the gate electrode and the first oxide semiconductor layer and including at least one combination of elements selected from the group consisting of silicon and nitrogen, titanium and oxygen, and aluminum and oxygen; and
a first insulating layer including a first portion and a second portion, the gate electrode being between the first portion and the second portion in a third direction, the first portion contacting the first gate insulating layer, and the second portion being contacting the gate electrode.

2. The semiconductor device according to claim 1, wherein a maximum distance in the third direction between an outer edge of the first oxide semiconductor layer on a first portion side and an outer edge of the gate electrode on a second portion side is greater than a maximum width of the gate electrode in the third direction.

3. The semiconductor device according to claim 1, wherein a maximum distance in the third direction between an outer edge of the first oxide semiconductor layer on a first portion side and an outer edge of the gate electrode on a second portion side is less than a maximum width of the gate electrode in the third direction.

4. The semiconductor device according to claim 3, wherein a width of the first oxide semiconductor layer contacting the second electrode is less than a width of the first oxide semiconductor layer contacting the first electrode.

5. The semiconductor device according to claim 4, wherein a center position of a portion of the first oxide semiconductor layer facing the gate electrode in the third direction is offset in the third direction from a center position of a portion of the first oxide semiconductor layer contacting the first electrode.

6. The semiconductor device according to claim 1, wherein a minimum distance in the third direction between the first gate insulating layer and an outer edge of the gate electrode on a second portion side is at least one-third of a maximum width of the gate electrode in the third direction.

7. The semiconductor device according to claim 1, wherein the first gate insulating layer has a stacked structure including a first film and a second film, the second film having a chemical composition different from that of the first film.

8. The semiconductor device according to claim 7, wherein the second film is between the first film and the first oxide semiconductor layer.

9. The semiconductor device according to claim 8, wherein the second film comprises silicon and oxygen.

10. The semiconductor device according to claim 1, further comprising:
a second oxide semiconductor layer spaced in the first direction from the first oxide semiconductor layer; and
a second gate insulating layer surrounding the second oxide semiconductor layer, the second gate insulating layer being between the gate electrode and the second oxide semiconductor layer and including the same at least one combination of elements as the first oxide semiconductor layer, wherein
the second gate insulating layer contacts the first portion of the first insulating layer.

11. The semiconductor device according to claim 10, further comprising:
a third oxide semiconductor layer at position between the first oxide semiconductor layer and the second oxide semiconductor layer in the first direction but offset in the third direction; and
a third gate insulating layer surrounding the third oxide semiconductor layer, the third gate insulating layer being between the gate electrode and the third oxide semiconductor layer and including the same at least one combination of elements, wherein
the third gate insulating layer contacts the second portion of the first insulating layer.

12. A semiconductor memory device, comprising:
a semiconductor device according to claim 1; and
a capacitor electrically connected to either the first electrode or the second electrode.

13. A semiconductor memory device, comprising:
a first electrode;
a second electrode;
a capacitor electrically connected to one of the first or second electrodes;
a gate electrode extending in a first direction;
a first oxide semiconductor column extending in a second direction through a portion of the gate electrode, the first oxide semiconductor layer extending in the second direction between the first electrode and the second electrode, the gate electrode facing the first oxide semiconductor column at a position between the first and second electrodes in the second direction;
a first gate insulating layer surrounding the first oxide semiconductor column, the first gate insulating layer being between the gate electrode and the first oxide semiconductor column and including at least one pair of elements selected from the group consisting of silicon and nitrogen, titanium and oxygen, and aluminum and oxygen; and
a first insulating layer including a first portion and a second portion, the gate electrode being between the first portion and the second portion in a third direction, the first portion contacting the first gate insulating layer, and the second portion being contacting the gate electrode.

14. The semiconductor memory device according to claim 13, wherein a maximum distance in the third direction between an outer edge of the first oxide semiconductor column on a first portion side and an outer edge of the gate electrode on a second portion side is greater than a maximum width of the gate electrode in the third direction.

15. The semiconductor memory device according to claim 13, wherein a maximum distance in the third direction between an outer edge of the first oxide semiconductor column on a first portion side and an outer edge of the gate electrode on a second portion side is less than a maximum width of the gate electrode in the third direction.

16. The semiconductor memory device according to claim 15, wherein a width of the first oxide semiconductor column contacting the second electrode is less than a width of the first oxide semiconductor column contacting the first electrode.

17. The semiconductor memory device according to claim 16, wherein a center position of a portion of the first oxide semiconductor column facing the gate electrode in the third direction is offset in the third direction from a center position of a portion of the first oxide semiconductor column contacting the first electrode.

18. The semiconductor memory device according to claim 13, wherein a minimum distance in the third direction between the first gate insulating layer and an outer edge of the gate electrode on a second portion side is at least one-third of a maximum width of the gate electrode in the third direction.

19. The semiconductor memory device according to claim 13, further comprising:
a second oxide semiconductor column spaced in the first direction from the first oxide semiconductor column; and
a second gate insulating layer surrounding the second oxide semiconductor column, the second gate insulating layer being between the gate electrode and the second oxide semiconductor column and including the same at least one pair of elements as the first oxide semiconductor column, wherein
the second gate insulating layer contacts the first portion of the first insulating layer.

20. The semiconductor memory device according to claim 19, further comprising:
a third oxide semiconductor column at position between the first oxide semiconductor column and the second oxide semiconductor column in the first direction but offset in the third direction; and
a third gate insulating layer surrounding the third oxide semiconductor column, the third gate insulating layer being between the gate electrode and the third oxide semiconductor column and including the same at least one pair of elements, wherein
the third gate insulating layer contacts the second portion of the first insulating layer.
